(19) United States
(12) Patent Application Publication
(10) Pub. No.: US 2024/0363683 A1
(43) Pub. Date: Oct. 31, 2024

(54) NON-CONDUCTING EDGE TERMINATION STRUCTURES FOR A SEMICONDUCTOR DEVICE AND METHODS OF FABRICATING THE SAME

(71) Applicant: IDEAL SEMICONDUCTOR DEVICES, INC., Bethlehem, PA (US)

(72) Inventors: David Jauregui, Bethlehem, PA (US); Stanislav Soloviev, Breinigsville, PA (US); Philip Rutter, Bethlehem, PA (US)

(21) Appl. No.: 18/647,072

(22) Filed: Apr. 26, 2024

Related U.S. Application Data
(60) Provisional application No. 63/498,962, filed on Apr. 28, 2023.

(51) Int. Cl. H01L 29/06; H01L 21/3065; H01L 29/40

(52) U.S. Cl. CPC H01L 29/0661; H01L 21/3065; H01L 29/401; H01L 29/404; H01L 29/408

(57) ABSTRACT

A method of forming an edge termination structure in a semiconductor device is provided. The method includes: forming an epitaxial layer on a semiconductor substrate, the epitaxial layer extending laterally across active and edge termination regions in the device; forming active trenches in the active region and at least one outer trench in the edge termination region, each of the outer and active trenches extending vertically through at least a portion of the epitaxial layer; at least partially filling each of the outer and active trenches with a first insulating material; forming a moat by etching an area of the epitaxial layer in the edge termination region proximate to a last one of the plurality of active trenches in the active region; and at least partially filling the moat with a second insulating material to form a moat structure as an edge termination structure in the semiconductor device.

### CROSS-REFERENCE TO RELATED APPLICATION(S)

This application claims the benefit of and priority under 35 U.S.C. § 119 to U.S. Provisional Application No. 63/498,962, filed on Apr. 28, 2023, entitled “Non-conducting Edge Termination Structures for a Semiconductor Device and Methods of Fabricating the Same,” the disclosure of which is incorporated by reference herein in its entirety for all purposes.

### BACKGROUND

The present invention relates generally to semiconductor devices and fabrication, and, more particularly, to enhanced edge termination structures for use in a semiconductor device, and methods of fabricating such structures.

Vertically conducting semiconductor devices in an integrated circuit (IC) include an active region that is surrounded by an edge termination region. In such vertical devices, the edge of the die is invariably at the same or similar voltage potential as that of a bottom of the device due primarily to saw damage when the device is singulated, or lack of a blocking junction at the edge of the device. Therefore, an edge termination region is an important part of the device design to ensure lateral blocking of potentially damaging voltages between the active region and the edge of the die.

While the active region only needs to withstand the blocking voltage in the vertical direction, the edge termination region must be able to withstand the blocking voltage in both the lateral and vertical directions. The requirement of an edge termination region to maintain a voltage blocking capability in both the vertical and lateral directions makes the design of the edge termination region of the device a critical factor in determining the performance and cost effectiveness of the device.

For semiconductor devices employing charge balance in the active region of the device, the design of the edge termination region is further complicated by a requirement to “charge balance” a last active cell of the device.

### SUMMARY

The present invention, as manifested in one or more embodiments, beneficially provides an enhanced edge termination structure for use in a charge balanced semiconductor device. In one or more embodiments, the edge termination structure is configured to isolate an active region in the semiconductor device by surrounding the active region with insulating material. Furthermore, while planar edge termination structures are more traditional, aspects of the present inventive concept beneficially provide both vertical and lateral voltage blocking.

In accordance with an embodiment of the invention, a method of forming an edge termination structure in a semiconductor device is provided. The method includes: forming an epitaxial layer on a semiconductor substrate, the epitaxial layer extending laterally across active and edge termination regions in the device; forming active trenches in the active region and at least one outer trench in the edge termination region, each of the outer and active trenches extending vertically through at least a portion of the epitaxial layer; at least partially filling each of the outer and active trenches with a first insulating material; forming a moat by etching an area of the epitaxial layer in the edge termination region proximate to a last one of the plurality of active trenches in the active region; and at least partially filling the moat with a second insulating material to form a moat structure as an edge termination structure in the semiconductor device.

In accordance with another embodiment, a semiconductor device is provided having an active region and an edge termination region, the edge termination region being laterally adjacent to the active region. The semiconductor device includes an epitaxial layer formed on a semiconductor substrate, the epitaxial layer extending laterally across the active and edge termination regions. The semiconductor device further includes a plurality of active trench structures and at least one active device formed in the active region, each of the active trench structures extending vertically through at least a portion of the epitaxial layer and being at least partially filled with a first insulating material. At least one outer trench structure is formed in the edge termination region of the semiconductor device, the outer trench structure extending vertically through at least a portion of the epitaxial layer and being at least partially filled with the first insulating material. The outer trench structure is proximate to a last one of the plurality of active trench structures in the active region. The semiconductor device further comprises a moat structure extending vertically through at least a portion of the epitaxial layer in the edge termination region, the moat structure having a sidewall defined by the at least one outer trench structure, the moat structure being at least partially filled with a second insulating material. The moat structure forms an edge termination structure in the semiconductor device configured to laterally isolate the active region from a reverse voltage in the semiconductor device.

As the term may be used herein, “facilitating” an action includes performing the action, making the action easier, helping to carry the action out, or causing the action to be performed. Thus, by way of example only and without limitation, in the context of a processor-implemented method, instructions executing on one processor might facilitate an action carried out by instructions executing on a remote processor, by sending appropriate data or commands to cause or aid the action to be performed. For the avoidance of doubt, where an actor facilitates an action by other than performing the action, the action is nevertheless performed by some entity or combination of entities.

Techniques of the present invention can provide substantial beneficial technical effects. By way of example only and without limitation, techniques according to embodiments of the invention may provide one or more of the following advantages, among other benefits:
provides a compact edge termination region that minimizes additional semiconductor area consumption;
minimizes additional process steps, thereby reducing overall cost and fabrication complexity and improving yield;
provides an edge termination region that achieves a high breakdown voltage consistent with that in the active region, and can charge balance the last cell of the edge termination region;
compatible with other edge termination features that are used to improve an effectiveness of edge termination structures, including, for example, inner field plates, outer field plates, junction termination extensions (JTEs), variable lateral diffusion (VLD), and charged or resistive layer on surface;
maximizes the breakdown voltage of the edge termination region.

These and other features and advantages of the present invention will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 is a schematic cross-sectional view depicting at least a portion of an exemplary integrated circuit (IC) die, according to one or more embodiments of the present inventive concept;

FIG. 2 is a flow diagram depicting at least a portion of intermediate process steps in an exemplary method for fabricating an edge termination structure for use in a semiconductor device, according to one or more embodiments of the present inventive concept;

FIGS. 3A-3E are schematic cross-sectional views depicting at least a portion of intermediate processes for fabricating an exemplary semiconductor device employing a non-conducting edge termination structure, according to one or more embodiments of the present inventive concept;

FIGS. 4A-4D are schematic cross-sectional views depicting at least a portion of an exemplary semiconductor device employing various configurations of inner and/or outer field plates, according to illustrative embodiments of the present inventive concept;

FIG. 5 is a schematic cross-sectional view depicting at least a portion of the semiconductor device shown in FIG. 4A with the field plate removed, and conceptually illustrating charge balancing in the device, according to one or more embodiments of the present invention;

FIGS. 6A and 6B are schematic plan views depicting at least a portion of a corner structure in a semiconductor device employing a moat edge termination structure, conceptually illustrating a manner in which capacitance of the moat structure may be determined at the corner;

FIGS. 7A-7C are schematic plan views conceptually depicting at least a portion of exemplary configurations of a corner structure in a semiconductor device employing a moat edge termination structure, according to embodiments of the present invention;

FIG. 8 is a schematic plan view depicting at least a portion of an exemplary corner of a semiconductor device employing a moat edge termination structure and a chamfered inner boundary trench, according to one or more embodiments of the present invention; and

FIGS. 9-16 are schematic plan views depicting at least a portion of several non-limiting examples of illustrative corner structures that may be used in an edge termination region of a semiconductor device employing a moat edge termination structure, in accordance with embodiments of the present invention.

It is to be appreciated that elements in the figures are illustrated for simplicity and clarity. Common but well-understood elements that may be useful or necessary in a commercially feasible embodiment are not necessarily shown in order to facilitate a less hindered view of the illustrated embodiments.

### DETAILED DESCRIPTION

Principles of the present invention, as manifested in one or more embodiments thereof, will be described herein in the context of illustrative edge termination structures configured to withstand a blocking voltage in both lateral and vertical directions, and methods for fabricating such structures. The novel edge termination structures according to embodiments of the invention are suitable for use in a charge balanced semiconductor device, and may have beneficial application, for example, in a power device or power system environment for providing direct current (DC)-DC or alternating current (AC)-DC conversion. It is to be appreciated, however, that the present inventive concepts are not limited to the specific structures and/or methods illustratively shown and described herein. Rather, it will become apparent to those skilled in the art given the teachings herein that numerous modifications can be made to the embodiments shown that are within the scope of the claimed invention. That is, no limitations with respect to the embodiments shown and described herein are intended or should be inferred.

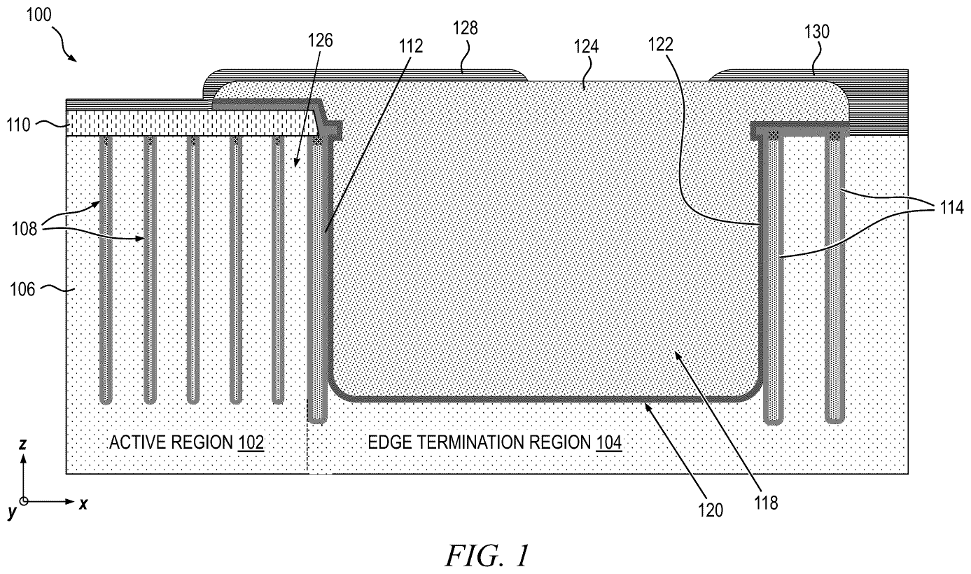

FIG. 1 is a schematic cross-sectional view depicting at least a portion of an exemplary integrated circuit (IC) die 100, according to one or more embodiments of the present inventive concept. The IC die 100, which may comprise one or more vertically conducting devices, may include an active region 102 that is surrounded by an edge termination region 104. In one or more embodiments, the active region 102 may comprise an n-type epitaxial layer 106 in which a layer of p-type material (not explicitly shown) is preferably formed proximate an upper surface of the epitaxial layer (depending on the type of device being formed), although embodiments of the invention are not limited to this specific arrangement. For example, in some embodiments, a p-type epitaxial layer 106 may be employed. As will be known by those skilled in the art, n-type material used to form the epitaxial layer 106, which may be referred to herein as a drift region, can be formed by doping semiconductor material (e.g., silicon) with an n-type (donor) dopant element, such as, for example, phosphorous, arsenic, etc., at a prescribed doping concentration. Likewise, the p-type material layer can be formed by doping the semiconductor material with a p-type (acceptor) dopant element, such as, for example, boron, at a prescribed doping concentration.

In vertically conducting devices, an edge of the IC die 100 is invariably at the same or similar voltage potential as that of a bottom surface of the device, due primarily to saw damage when the device is singulated (i.e., separated) or lack of a blocking junction at the edge of the device. Therefore, there is a need to not only block voltages between the top and bottom surfaces of the vertical device, but also to block voltages laterally between the active region 102 of the device and edge of the IC die 100; the edge termination region 104 is the region in the device that provides this lateral voltage blocking capability.

The active region 102 may include a plurality of active trench structures 108. Each of the active trench structures 108 may extend at least partially through the epitaxial layer 106 in a substantially vertical direction (z direction). In one or more embodiments, the active trench structures 108 extend at least twenty-five percent (25%) through the epitaxial layer 106; in some embodiments, the active trench structures 108 may extend entirely through the epitaxial layer 106 and into an underlying substrate (not explicitly shown, but implied) on which the epitaxial layer may be formed. A first metal layer 110 may be formed over an upper surface of the active trench structures 108. In one or more embodiments, the active trench structures 108 may be used for charge balancing at least a portion of the active region 102.

The edge termination region 104 may include at least one outer trench structure 112. The outer trench structure 112 may be formed at least partially through the epitaxial layer 106 in a substantially vertical direction (z direction) and may extend along a y direction, orthogonal to the z direction. Although not required, the same trench processing, which may include etching, trench filling, etc., is preferably used to form both the active trench structures 108 and the outer trench structure 112; that is, the same mask and trench etch process can be used to form the active trench structures 108 and the outer trench structure 112, thus reducing costs.

Optionally, one or more boundary trench structures 114 may be formed in the edge termination region 104 at least partially through the epitaxial layer 106 in a substantially vertical direction (z direction). The boundary trench structures 114 may be spaced laterally (e.g., in an x direction) from the outer trench structure 112 by a “moat” structure 118 formed therebetween in the epitaxial layer 106. The term “moat” as used herein is intended to refer broadly to a region adjacent to an active region (e.g., 102) where part of the epitaxial silicon is removed and at least partially filled with an insulating material. The term “filled” (or “filling,” “fill,” or like terms), as may be used herein, is intended to refer broadly to either completely filling a defined space (e.g., the moat structure 118) or partially filling the defined space; that is, the defined space need not be entirely filled but may, for example, be partially filled or have voids or other spaces throughout. The moat structure 118 may be formed as a RESURF (reduced surface field) structure, in one or more embodiments.

Generally, the moat will surround the active region, but configurations are contemplated where the moat may be present on less than all sides of the active region (e.g., a couple of sides only). The term “surround” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles. Although not critical, in one or more embodiments, a width (in the x direction) of the outer trench structure 112 and the boundary trench structures 114 may be larger relative to a width (in the x direction) of the active trench structures 108. For example, in some embodiments, the width of the outer trench structure 112 is about twice (2×) the width of the active trench structures 108. Preferably, the width of the outer trench structure 112 is about 2 microns (μm) and the width of each of at least a subset of the active trench structures 108 is about 1 μm, although embodiments are not limited thereto. This allows the outer trench structure 112 to be etched deeper, which thereby beneficially provides more process margin in forming the edge termination structure. A spacing between adjacent active trench structures 108 (i.e., pitch) may be about 4 μm, although embodiments of the invention are not limited thereto.

The moat structure 118 may be defined by a trench 120, which may be formed by removing a portion of the epitaxial layer 106 in the edge termination region 104, between the outer trench structure 112 and one of the boundary trench structures 114. A vertical depth of the trench 120 in the z direction (relative to an upper surface of the epitaxial layer 106) may generally be similar to a vertical depth of the active trenches, and is preferably less than a depth of the outer trench structure 112 (e.g., about 20 μm). By way of example only, in the exemplary IC die 100, the trench 120 and trench structures 108 may be formed having a depth of about 20 μm and the trench structures 112 and 114 may be formed having a depth of about 22 μm, although embodiments are not limited thereto. An insulating layer 122 may be formed on at least sidewalls and a bottom of the trench 120. The insulating layer 122 may conformally cover inner surfaces of the trench 120. The term “conformally” (or “conformal,” or like terms), as may be used herein in the context of a material layer or coating, is intended to refer broadly to a material layer or coating having a substantially uniform cross-sectional thickness relative to the contour of a surface to which the material layer is applied. The term “cover” (or “covering,” or like terms), as may be used herein, is intended to broadly refer to an element, structure or layer that is on or over another element, structure or layer, either directly or with one or more other intervening elements, structures or layers therebetween.

The insulating layer 122 may extend along sidewalls of the trench 120 and at least partially into the active region 102, such as over at least a subset of the active trench structures 108. Additionally or alternatively, the insulating layer 122 may extend at least partially into the edge termination region 104, such as over at least a subset of the boundary trench structures 114. In one or more embodiments, the insulating layer 122 may comprise, for example, silicon oxynitride (SiOₓN_{y}), silicon nitride (SiN), etc., although embodiments are not limited thereto.

The trench 120 may be at least partially filled with an insulating material 124, such as, for example, polyimide or another polymer or organic material, to ultimately form the moat structure 118. A standard deposition process may be used to fill the trench 120. The insulating material 124 may at least partially extend onto an upper surface of the IC die 100, over an upper end of one or more of the active trench structures 108 in the active region 102 and/or one or more of the boundary trench structures 114 in the edge termination region 104.

The moat structure 118, including the insulating layer 122 and insulating material 124, in conjunction with the outer and boundary trench structures 112, 114, beneficially forms an edge capacitor that may be used for edge termination; the outer and boundary trench structures 112, 114 proximate opposing sidewalls of the moat structure 118, enclose the edge capacitor in the edge termination region 104. Edge terminations are generally either capacitive (i.e., voltage blocked across an insulator) or may use a blocking junction in the semiconductor (e.g., a p-n diode). In some embodiments, a combination of these two options may be employed, where some of the voltage is dropped laterally (i.e., horizontally, parallel to the upper surface of the substrate) via a depletion region/blocking junction followed by a moat structure to block the remaining voltage.

Edge termination in the IC die 100 may be configured such that the induced charge due to the edge capacitor is minimal. Charge balance in the IC die 100 may be achieved by configuring a width of a last active mesa 126 (i.e., a region of the epitaxial layer 106 between a last one of the plurality of active trench structures 108 in the active region 102 and a first (or only) outer trench structure 112 in the edge termination region 104) to account for additional charge due to the edge capacitor and charges in the insulating material 124. The plates of the edge capacitor may comprise a sidewall of the outer trench structure 112 adjacent to the moat structure 118 and a sidewall of the boundary trench structure 114 adjacent to the moat structure 118, with the insulating material 124 serving as the dielectric layer between the two capacitor plates.

In one or more embodiments, the IC die 100 may include a second metal layer forming an inner field plate 128 on at least a portion of an upper surface of the first metal layer 110 and over at least a portion of an upper surface of the insulating layer 124 of the moat (e.g., RESURF) structure 118. The inner field plate 128 may comprise a conductive material, such as, for example, a metal. The first metal layer 110 and the inner field plate 128 may, in some embodiments, be formed of the same material, although in other embodiments, the first metal layer 110 and the inner field plate 128 may be formed of different materials. It is to be appreciated that although the exemplary IC die 100 is shown as including two levels of metal, with the inner field plate 128 being formed of the second metal layer, in one or more alternative embodiments, the inner field plate 128 may be formed as an extension of the first metal layer.

The inner field plate 128 may be electrically connected to at least a subset of the active trench structures 108 and/or to a voltage source (e.g., ground) and is configured to control an electric field distribution in the edge termination region 104. Specifically, the inner field plate 128 may be configured as an electrode disposed over at least a portion of the moat structure 118 to redistribute the electric field away from the active region 102 and to mitigate a peaking of the electric field in the edge termination region 104 and in the active region 102 proximate the edge termination region 104, such as in or near the last active mesa 126. In general terms, field plates help reduce the maximum electric field, achieve a desirable electrical field profile across a defined region (e.g., moat structure 118), and increase breakdown voltage of the device. The amount of lateral (i.e., horizontal) extension of the inner field plate 128 over the moat structure 118, in the x-direction and/or y-direction, may be adjusted to control a profile of the electric field distribution in the edge termination region 104 and in the region of active area adjacent to the moat structure 118.

Optionally, the IC die 100 may further include an outer field plate 130 formed over at least a portion of the upper surface of the insulating layer 124, proximate the boundary trench structures 114. The outer field plate 130 may be electrically connected to one or more of the boundary trench structures 114, and may be configured to confine the electric fields to inside the insulating materials (e.g., insulating layer 124) of the moat structure 118. In a manner consistent with the configuration of the inner field plater 128, the amount of extension of the outer field plate 130 over the moat structure 118 (in the x-direction and/or y-direction) may be adjusted to control the electric field distribution in the edge termination region 104.

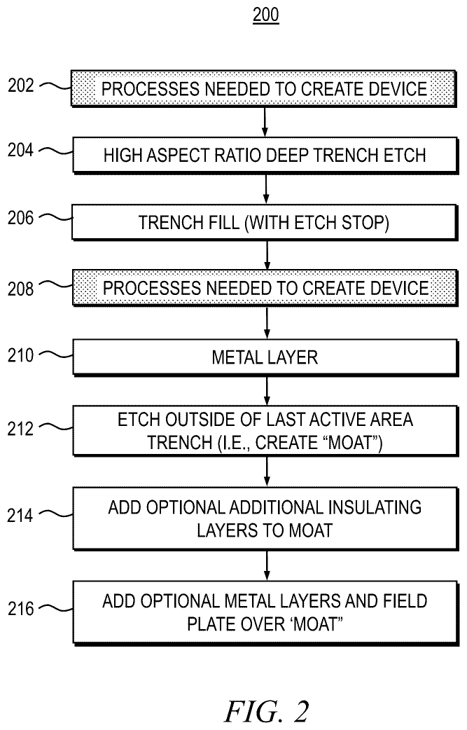

FIG. 2 is a flow diagram depicting at least a portion of intermediate processes performed in an exemplary method 200 for fabricating an edge termination structure for use in a semiconductor device, according to one or more embodiments of the invention. Although the processes performed in the exemplary method 200 may be described herein in a particular order, it is to be appreciated that embodiments of the invention are not necessarily limited to the specific order described. Furthermore, additional processes (not explicitly shown) may be performed in fabricating a completed semiconductor device, such additional processes being performed before, after or in between the processes used in forming the edge termination structure according to embodiments of the inventive concept.

With reference to FIG. 2, the exemplary fabrication method 200 may include processes 202 involved in creating one or more active region devices and/or structures, including, for example, high thermal budget processes (e.g., ion implantation, rapid thermal processing (RTP), annealing, etc.). These processes used in fabricating the active region devices, or at least a portion of such processes, may be performed before processes involved in fabricating the edge termination structure are initiated. Next, a high aspect ratio (e.g., about 20:1) deep trench etch process 204 may be performed, followed by a trench fill process 206 including an etch stop layer. The deep trench etch process 204 and trench fill process may be used to form active trench structures (e.g., 108 in FIG. 1) in an active region of the device and/or outer trenches defining sidewalls of a moat structure (e.g., 118 in FIG. 1) and, optionally, boundary trench structures (e.g., 114 in FIG. 1) in an edge termination region of the device. One or more additional processes 208 involved in fabricating the active region devices and/or structures may be subsequently performed.

Next, a first metal layer process 210 may be performed. The first metal layer process 210 may be used to form electrodes for providing electrical connection to the active region devices. In process step 212, an etch may be performed outside of a last active trench structure in the active region (adjacent to an edge termination region of the device) to form a wide trench (e.g., 120 in FIG. 1) that will be subsequently used as a moat edge termination structure in the device. One or more insulating layers may be added to the edge termination region trench in process 214, such as by conformally forming one or more insulating layers on sidewalls and/or a bottom surface of the edge termination region trench. Next, at least a second metal layer process 216 may be optionally performed for fabricating one or more metal layers over at least a portion of the moat edge termination structure in the edge termination region of the device. These additional metal layers can be used to form an inner field plate (e.g., 128 in FIG. 1) and/or an outer field plate (e.g., 130 in FIG. 1) in the device.

The illustrative fabrication method 200 can be beneficially employed for various different types of active region devices (e.g., metal-oxide semiconductor (MOS) transistors, Schottky devices, etc.). Accordingly, it is to be understood that integration of edge termination structures according to aspects of the present inventive concept with the various active region devices may involve some of the processes necessary for the active device fabrication being interspersed between processes required for fabricating the novel edge termination structure, depending on the type of active device(s) being formed.

For example, one or more implants requiring a high thermal budget (e.g., greater than about 1000° C.) may be performed at a start of the fabrication process. A gate trench formation process may be performed either before or after the deep trench etch and fill process. Shallow implants (e.g., as may be used in creating source and drain regions in the active region of the device) requiring minimal thermal budgets (e.g., less than about 1000° C.) may be performed following the trench fill process. Forming active trenches (e.g., 108 bin FIG. 1) typically has a “high” thermal budget (due at least in part to sacrificial oxidations and depositions of films in the trenches that may be performed). Therefore, parts of forming a device that require a “low” thermal budget should be done after the active trenches are formed (e.g., shallow junctions); deep junctions that may require a high thermal budget can be done beforehand.

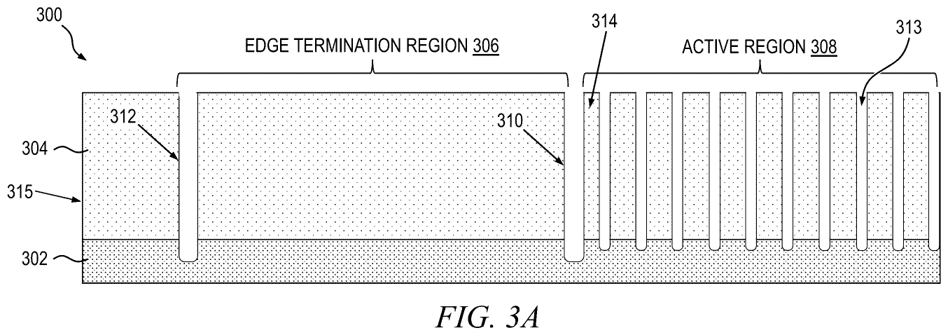

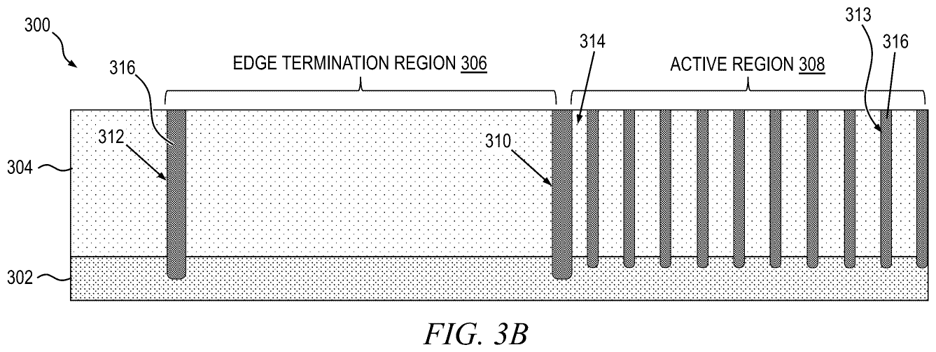

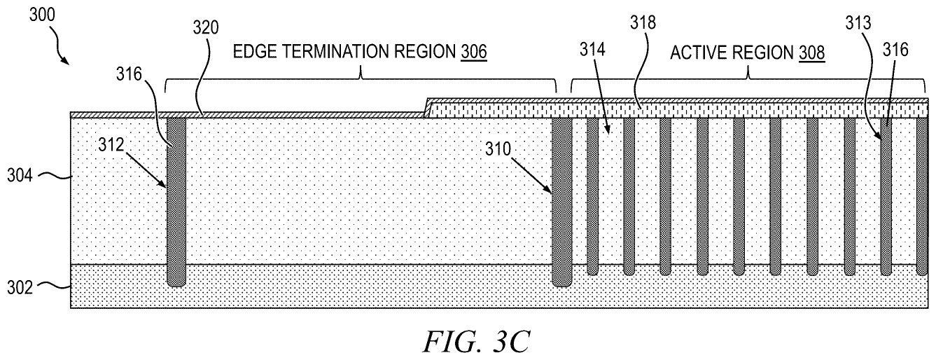

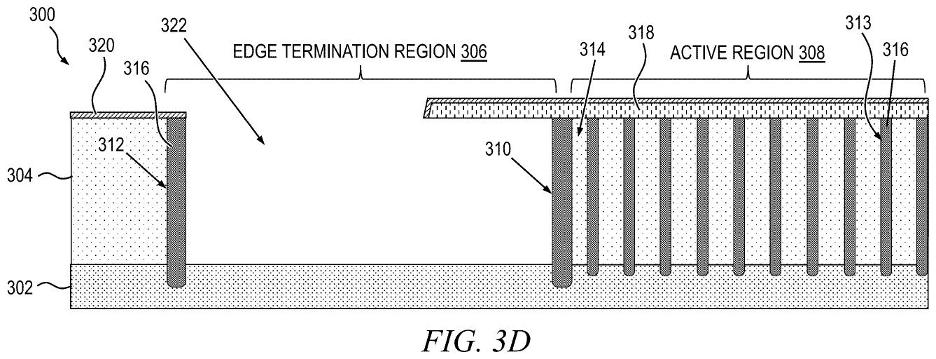

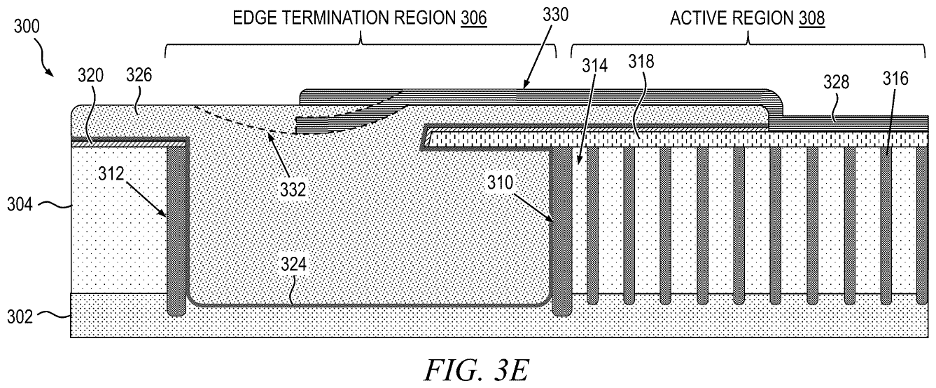

FIGS. 3A-3E are schematic cross-sectional views depicting at least a portion of intermediate processes for fabricating a semiconductor die 300 employing a non-conducting edge termination structure, according to one or more embodiments of the invention. Although FIGS. 3A-3E may be directed to the fabrication of a Schottky device, it is to be understood that embodiments of the invention are not limited to the formation of a Schottky device. Rather, aspects of the inventive concept may be used to formation various other semiconductor devices, including MOS transistors and the like, as will become apparent to those skilled in the art given the teachings herein.

With reference to FIG. 3A, an exemplary deep trench etch process is illustrated, according to one or more embodiments. More particularly, the semiconductor die 300 may include a substrate 302, which may be doped with an n-type or p-type impurity of a known dopant concentration level. An epitaxial layer 304 (e.g., comprising silicon (Si), silicon carbide (SiC), etc.), which may also be referred to herein as a drift region, may be formed on at least a portion of the substrate 302; the epitaxial layer 304 may be formed using a standard epitaxial process. For example, an n-type epitaxial layer 304 may be formed by doping semiconductor material (e.g., silicon) with an n-type (donor) dopant element at a prescribed doping concentration. Likewise, a p-type epitaxial layer 304 can be formed by doping the semiconductor material with a p-type (acceptor) dopant element at a prescribed doping concentration.

The semiconductor die 300 may include an edge termination region 306, in which an edge termination structure according to embodiments of the invention is formed, and an active region 308, in which one or more active devices (e.g., Schottky device, MOSFET, etc.) may be formed. The edge termination region 306 preferably includes at least one outer trench 310 and, optionally, at least one boundary trench 312; the active region 308 may include a plurality of active trench 313. Each of the trenches preferably extends substantially vertically (i.e., perpendicular to an upper surface of the substrate 302) at least partially into or through the drift region 304, and may extend partially into the substrate 302, in one or more embodiments.

The outer trench 310 may also be considered a “boundary” trench, since it is disposed in the edge termination region 306 of the device. Therefore, the outer trench 310 may be referred to herein as an “inner boundary trench,” and the boundary trench 312 may be referred to as an “outer boundary trench;” these terms may be used interchangeably throughout the specification.

In one or more embodiments, the trenches 310, 312, 313 may be formed using a high aspect ratio deep trench etch process, such as, for example, deep reactive ion etching (DRIE). Advantageously, the same trench mask and etch process may be used for forming the trenches in both the edge termination region 306 and the active region 308. For the trench etch process, a trench mask may be used which comprises a photoresist mask or hard mask (e.g., a thin film of silicon dioxide (SiO₂) and/or silicon nitride (SiN) that is patterned using a standard photolithographic process). The outer trench 310 may be formed having the same dimensions as the active trenches 313, although in one or more embodiments, the outer trench 310 (and the boundary trench 312, if present) may be formed wider (in a horizontal direction) than the active trenches 313. This enables the outer trench 310 to be etched deeper, which in turn allows more process margin for forming a moat structure used in the edge termination structure, since the moat structure should not be deeper than the outer trench 310. For example, in some embodiments, a width (in the horizontal direction) of each of at least a subset of the active trenches 313 may be about 1 μm and a width of the outer trench 310 may be about 2 μm, although the present inventive concept is not limited to any specific dimensions for the trenches.

A last mesa 314 in the active region 308 may be defined as a region of the epitaxial layer 304 between a last active trench of the plurality of active trenches 313 and the outer trench 310 in the edge termination region 306. In one or more embodiments, a width of the last mesa 314 may be configured to beneficially control (i.e., optimize) charge balance in the last mesa, to thereby account for a difference in charge due to the moat structure (to be formed between the outer trench 310 and the boundary trench 312) in the edge termination region 306. Optionally, the boundary trench 312 will define an outer boundary of the moat structure; if the boundary trench 312 is omitted, the outer trench of an adjacent die formed on the same wafer (before dicing) effectively becomes the boundary trench for defining a width of the moat structure. Although only one boundary trench 312 is shown in the illustrative embodiment of FIG. 3A, it is to be appreciated that one or more additional “dummy” boundary trenches may be formed outside of the boundary trench proximate to an edge 315 of the semiconductor die 300, in accordance with some embodiments.

With reference to FIG. 3B, an exemplary trench fill process is illustrated, according to one or more embodiments. Specifically, in the semiconductor die 300, a surface of the sidewalls and bottom of each of at least a subset of the active trenches 313, the outer trench 310 and boundary trench 312 may be smoothed to remove etch damage or other imperfections, preferably with a sacrificial oxide. The trenches are then at least partially filled with one or more insulating layers 316 (e.g., SiO₂), which may include an air gap. Note, that the first insulating layer 316 deposited in the trenches may be used as an etch stop layer for a subsequent moat etch process.

Although not explicitly shown (but implied), the trench fill process may also incorporate the deposition of layers that introduce fixed charge to create a charge balance structure; that is, the insulating layer(s) 316 may comprise one or more fixed charge layers. For example, alumina (Al₂O₃), which has a net negative static charge associated therewith, may be deposited inside at least a subset of the active trenches 313, for example using an atomic layer deposition (ALD) process. Alternatively, for a device using n-type epitaxial layer 304, thin doped epitaxial layers could be grown on the sidewalls of the trenches prior to filling, or a p-type species (i.e., dopant) may be diffused into the mesas (e.g., mesa 314) between adjacent active trenches 313 via the trench sidewalls prior to the trench fill process.

The outer and boundary trenches 310, 312 may be formed concurrently with the active trenches 313 using the same process. In this manner, the outer and boundary trenches 310, 312 may have the same fixed charge as the active trenches 313. Using the same processing to form the outer and boundary trenches 310, 312 as the active trenches 313 may have advantages, at least from a cost perspective. It is to be appreciated, however, that embodiments are contemplated in which the outer and boundary trenches 310, 312 are processed differently compared to the active trenches 313, particularly if it is desirable to avoid adding fixed charge to the outer and boundary trenches or to form outer and boundary trenches 310, 312 having a different fixed charge (or no fixed charge) relative to the active trenches 313. Once filled, each of the trenches 310, 312, 313 may be referred to herein as a “trench structure,” which may be used interchangeably with the term “trench” depending on the context in which the term is used.

Following the trench fill process, some of the insulating layer material 316 may extend laterally (i.e., horizontally) onto at least a portion of an upper surface of the epitaxial layer 304. This portion of the insulating layer material extending on the upper surface of the epitaxial layer 304 may be removed, such as, for example, by chemical mechanical polishing (CMP) and/or etching (wet and/or dry etching), such that the upper surface of the semiconductor die 300 is substantially planar. Alternatively, the insulating layer 316 extending on the upper surface of the epitaxial layer 304 may be patterned and partially etched (e.g., using photolithography) and used as part of the device structure, in accordance with one or more embodiments.

With reference now to FIG. 3C, a metallization process is illustrated, according to one or more embodiments. The metallization process may be used to provide electrical connection (e.g., electrodes, wiring traces, etc.) to one or more devices formed in the active region 308 to complete the active region structure. The term “connection” (or “connecting,” or like terms such as, for example, “contact” or “contacting”), as may be used herein, is intended to refer to a physical and/or electrical connection between two or more elements, and may include other intervening elements. As used herein, the term “and/or” includes any and all combinations of one or more of the associated listed items.

By way of example only and without limitation, in the case of forming a Schottky device, the metallization process may involve depositing a first metal layer 318 on an upper surface of the active region 308, including upper surfaces of the active trench structures 313 and upper surfaces of the mesas (e.g., 314) between adjacent active trench structures. At least a portion of the first metal layer 318 may be patterned and configured to act as a Schottky barrier layer of the device. In one or more embodiments, the first metal layer 318 may extend (horizontally) on a portion of the upper surface of the epitaxial layer 304 in the edge termination region 306, including on an upper surface of the outer trench structure 310. However, the first metal layer 318, in the illustrative embodiment shown, does not extend over the boundary trench structure 312, so that at least a portion of the upper surface of the epitaxial layer 304 between the outer trench 310 and the boundary trench 312 is exposed. The term “exposed” (or “expose,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device.

A thin insulating layer 320 (e.g., about 0.1 μm thick, although embodiments are not limited thereto) may be formed over an upper surface of the die 300, including on at least a portion of an upper surface of the first metal layer 318 in the active region 308 and on at least a portion of the upper surface of the epitaxial layer 304 and first metal layer 318 in the edge termination region 306. This thin insulating layer 320, which may comprise, for example, silicon dioxide (or an alternative insulating material) formed using a deposition process or the like, may be used to protect the first metal layer 318 from subsequent processing and/or as an adhesion or stress relief layer for subsequent layers that may be provided on the first metal layer.

The first metal layer 318 and thin insulating layer 320 may act as a mask to protect the active region 308 during subsequent etching of the moat structure, as will be described in further detail below. During the moat etch process, the outer trench 310 and boundary trench 312 will preferably act as an etch stop for defining sidewalls of the moat structure. When an isotropic etch is used to form the moat structure (i.e., a process that selectively etches both laterally and vertically), then a field plate can be created by allowing the first metal layer 318 to extend partially into the edge termination region 306 between the outer trench 310 and boundary trench 312, since an isotropic etch will remove the silicon underneath the metal layer, stopping only when the etchant reaches the outer trench 310; if an isotropic etch is employed, the first metal layer 318 would preferably cover the last mesa 314 and all or at least part of the outer trench 310. Note, that it is possible to create the moat structure prior to the metallization process if a suitable moat fill material is used that can withstand the processes associated with deposition and etching of the metal.

Referring to FIG. 3D, an exemplary moat etch process is illustrated, according to one or more embodiments. Specifically, a moat 322 may be etched in the edge termination region 306. The moat 322 may be formed by removing a portion of the epitaxial layer 304 between the outer trench 310 and the boundary trench 312, preferably using an isotropic deep trench etch process. Typically, deep trench etches use an anisotropic etch to prevent lateral (i.e., sideways or horizontal) etching as the feature is etched into the silicon. In forming the moat 322 in the semiconductor die 300, however, the outer and boundary trenches 310, 312 serve as etch stops to ensure that that moat dimensions are correctly defined, which beneficially provides the option of using an isotropic etch. By using an isotropic etch to form the moat 322, the portion of the first metal layer 318 which extends over the upper surface of the edge termination region 306 will remain, thereby allowing the creation of a metal field plate in the edge termination region overlying a portion of the moat 322.

Note, that a width and depth of the moat 322 will be a function of one or more factors, such as, for example, a desired voltage blocking requirement of the device, field plate length (i.e., extension) over the moat 322, and properties of the material(s) used to line and/or fill the moat 322. Preferably, the depth of the moat 322 (in a vertical direction) may be close to a depth of the outer and boundary trenches 310, 312. Note, that if an isotropic etch is used to form the moat 322, the moat depth should not be greater than the depth of the outer trench 310, since the etch may remove material underneath the outer trench 310, which is undesirable. For at least this reason, it is advantageous (although not strictly necessary) for the outer and boundary trenches 310, 312 to be deeper than the active trenches 313. As previously stated, the outer and boundary trenches 310, 312 can be etched deeper by making them wider. In one or more embodiments, the width of the outer and boundary trenches 310, 312 is at least twice the width of the active trenches 313 (e.g., about 1 μm wide for the active trenches 313 and at least about 2 μm wide for the outer and boundary trenches 310, 312), although embodiments are not limited to any specific ratio of widths of the outer and boundary trenches 310, 312 to the active trenches 313.

In one or more illustrative embodiments, an extension of the first metal layer 318 over the moat 322 (in a horizontal direction) may be about equal to a depth (in a vertical direction) of the moat 322. For example, the moat 322 depth may be about 20 μm and an extension of the first metal layer 318 over the moat 322 may be about 18 μm, although the present inventive concept is not limited to any specific dimensions of the moat 322 and/or horizontal extension of the first metal layer 318 over the moat 322. The moat 322 may be etched vertically through the epitaxial layer 304 and partially into the substrate 302, although embodiments of the invention contemplate that the moat 322 may be etched only partially through the epitaxial layer 304 without extending into the substrate 302.

With reference to FIGS. 3D and 3E, an exemplary moat fill process is illustrated, according to one or more embodiments. Specifically, a first insulating or dielectric layer 324 may be formed on exposed inner surfaces of the moat 322, including sidewalls and a bottom of the moat 322, as well as on exposed surfaces of the extension of the first metal layer 318 and thin insulating layer 320, such as by a deposition process. The first insulating layer 324 may conformally cover the exposed surfaces of the moat 322, first metal layer 318 and thin insulating layer 320. The first insulating layer 324 may comprise, for example, silicon oxynitride or the like. Next, the moat 322 may be at least partially filled with a second insulating layer 326, on at least a portion of exposed surfaces of the first insulating layer 324. The second insulating layer 326 may be formed not only within the moat 322, but also on an upper surface of the first insulating layer 324 extending horizontally outside of the defined moat 322, such as over the first metal layer 318, extending partially into the active region 308. The second insulating layer 326 may comprise, for example, polyimide, although embodiments of the invention are not limited thereto. In one or more embodiments, the first and second insulating layers 324, 326 may comprise the same material(s), although in some embodiments the first and second insulating layers 324, 326 may comprise different materials.

For a typical power device, it may be known to have a silicon dioxide layer above the metal, followed by a silicon nitride or silicon oxynitride layer, followed by polyimide. In the integration according to aspects of the present inventive concept, those same materials may be employed. For example, in some embodiments, silicon dioxide may be deposited prior to the moat etch process (although the silicon dioxide may also be deposited after the moat etch). Following the moat etch process, a layer of silicon oxynitride may be deposited, followed by a polyimide deposition.

As shown in FIG. 3E, an optional second metal layer 328 may be formed on at least a portion of the first metal layer 318 in the active region 308, and on at least a portion of an upper surface of the second insulating layer 326, extending laterally into the edge termination region 306. An extension of the second metal layer 328 may be used to create a second field plate 330 over the moat 322. Note, that this second metal layer 328 may function as the only field plate for embodiments wherein the first metal layer 318 does not extend over the moat 322. The use of two field plates 318, 330, where the top field plate 330 extends further over the moat area in the edge termination region 306, can help to improve a curvature of the electric field as it transitions from a vertical direction in the active region 308 to a lateral (i.e., horizontal) direction across the moat 322 in the edge termination region 306.

Although the upper surface of the second insulating layer 326 over the moat 322 is shown as being planar with the upper surface of the second insulating layer lying outside of the moat area, there may be a dip in the upper surface of the second insulating layer 326, represented by dotted contour line 332. This dip 332 in the upper surface of the second insulating layer 326 over the moat 322 may result, for example, from the moat fill process; that is, an upper surface of the second insulating layer 326 in the moat 322 may not be planar, and therefore the second metal layer 328, which may follow a contour of the upper surface of the second insulating layer 326, may be non-planar. Accordingly, an end portion of the second metal layer forming the second field plate 330 may follow this dip 332 in the upper surface of the second insulating layer 326, which may influence, to some extent, the electric field distribution in the moat area. Creating such a dip 322 in the moat fill process to reduce the height of the metal field plate can be beneficial in optimizing the electric field curvature.

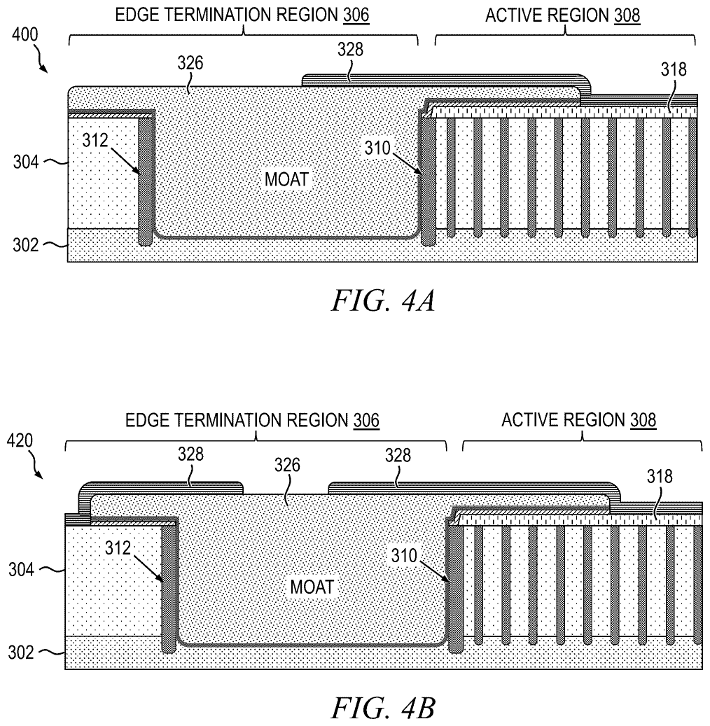

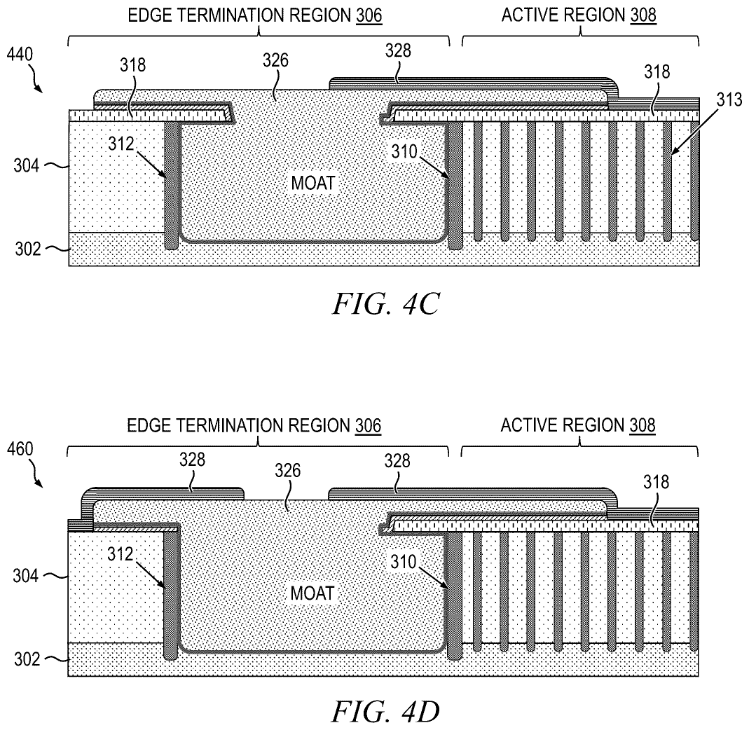

As will be described in further detail in conjunction with the illustrative embodiments shown in FIGS. 4B-4D, aspects of the present inventive concept contemplate the formation of field plates on an outer side of the moat 322 proximate the boundary trench 312, using the first metal layer 318 and/or the second metal layer 328.

By way of example only and without limitation or loss of generality, FIGS. 4A-4D are schematic cross-sectional views depicting at least a portion of an exemplary semiconductor device employing various configurations of inner and/or outer field plates in an edge termination region of the device, according to embodiments of the invention. Certain elements included in the semiconductor device, such as, for example, active trench structures, edge trench structures, outer trench structures, etc., may be formed in a manner consistent with corresponding elements previously described herein, and will therefore not be discussed further for clarity of description.

FIG. 4A depicts an exemplary semiconductor device 400 configured such that the second metal layer 328 forms a single inner field plate, according to some embodiments. Specifically, the semiconductor device 400 includes the first metal layer 318 formed proximate an upper surface of the active region 308. The first metal layer 318, unlike in the exemplary semiconductor device 300 shown in FIG. 3E, does not extend into the edge termination region 306, but rather ends at the outer trench 310 at an edge of the active region 308. The second metal layer 328 may be formed on at least a portion of the upper surface of the first metal layer 318 and is configured to extend laterally on the second insulating layer 326 over a portion of the moat structure (e.g., as defined by the moat 322 shown in FIG. 3D) in the edge termination region 306. This extension of the second metal layer 328 over the moat structure functions as a primary inner field plate in the absence of the extension of the first metal layer 318 over the moat structure.

With reference to FIG. 4B, an exemplary semiconductor device 420 is shown that includes inner and outer field plates formed from the second metal layer 328 extending laterally from both the outer trench 310 and the boundary trench 312 edges of the moat, according to some embodiments. More particularly, the semiconductor device 420, like the semiconductor device 400 of FIG. 4A, is configured such that the first metal layer 318 does not extend into the edge termination region 306, but rather ends in the active region 308 proximate the outer trench 310. A first part of the second metal layer 328 may be formed on at least a portion of the first metal layer 318 and extends laterally (i.e., horizontally) on the second insulating layer 326 over a portion of the moat structure in the edge termination region 306, proximate the outer trench 310, to form a primary inner field plate.

In a similar manner, the semiconductor device 420 may be further configured such that a second part of the second metal layer 328 is formed on at least a portion of the epitaxial layer 304 in the edge termination region 306 and over the second insulating layer 326 proximate the boundary trench 312. The second part of the second metal layer 328 preferably extends laterally over the moat structure from the boundary trench 312 edge towards the outer trench 310 edge of the moat structure. The extension of the second metal layer 328 over the moat structure forms a primary outer field plate. An amount of extension of the first and second parts of the second metal layer 328 over the moat structure may be controlled to achieve a desired electric field distribution in the moat structure. However, the first and second parts of the second metal layer 328 are not electrically connected to one another.

FIG. 4C depicts an exemplary semiconductor device 440 that includes primary inner and outer field plates formed from the first metal layer 318, and a secondary inner field plate formed from the second metal layer 328, according to some embodiments. Specifically, the semiconductor device 440 is configured such that the first metal layer 318 is formed over the active trenches 313 in the active region 308 and over at least a portion of the epitaxial layer 304 in the edge termination region 306. In this illustrative embodiment, a first part of the first metal layer 318 extends laterally (i.e., horizontally) from the active region 308, over the outer trench 310 and over a portion of the moat structure in the edge termination region 306, to form a primary inner field plate. Likewise, a second part of the first metal layer 318 extends laterally over the epitaxial layer 304, over the boundary trench 312 and over a portion of the moat structure in the edge termination region 306, to form a primary outer field plate. Thus, the first metal layer 318 forms primary inner and outer field plates over portions of the moat structure originating from both the outer trench 310 edge and the boundary trench 312 edge of the moat structure, respectively. A portion of the upper surface of the second insulating layer 326 in the moat structure may remain without any overlying field plate. An amount of extension of the first and second parts of the first metal layer 318 over the moat structure may be selectively varied to optimize an electric field distribution in the moat structure.

The semiconductor device 440 may be further configured having the second metal layer 328 formed on at least a portion of the first metal layer 318 and extending laterally on the second insulating layer 326 over a portion of the moat structure in the edge termination region 306, in a manner consistent with the arrangement of the second metal layer 328 shown in FIG. 3E. This extension of the second metal layer 328 over the moat structure may function as a secondary inner field plate. In this illustrative embodiment, the second metal layer 328 does not extend on the second insulating layer 326 from boundary trench 312 edge of the moat structure, although this arrangement is similarly contemplated by other embodiments of the invention.

With reference now to FIG. 4D, an exemplary semiconductor device 460 is shown having a primary outer field plate formed from the second metal layer 328, and having primary and secondary inner field plates formed from the first and second metal layers 318 and 328, respectively. Specifically, the semiconductor device 460 may be configured such that the first metal layer 318 is formed over the active trenches 313 in the active region 308 and extends laterally (i.e., horizontally) from the active region 308, over the outer trench 310 and over a portion of the moat structure in the edge termination region 306, to form a primary inner field plate. This is similar to the formation of the primary inner field plate shown in the semiconductor device 440 of FIG. 4C. In the illustrative semiconductor device 460, the first metal layer 318 does not extend over the moat structure from the boundary trench 312 side.

In the semiconductor device 460, a first part of the second metal layer 328 may be formed on at least a portion of the first metal layer 318 and may extend laterally on the second insulating layer 326 over a portion of the moat structure in the edge termination region 306, proximate the outer trench 310, to form a secondary inner field plate. The semiconductor device 460 may be further configured such that a second part of the second metal layer 328 is formed on at least a portion of the epitaxial layer 304 in the edge termination region 306 and over the second insulating layer 326 proximate the boundary trench 312. The second part of the second metal layer 328 preferably extends laterally over the moat structure from the boundary trench 312 edge towards the outer trench 310 edge. The extension of the second part of the second metal layer 328 over the moat structure forms a primary outer field plate. An amount of extension of the first and second parts of the second metal layer 328 over the moat structure may be selectively varied to achieve a desired electric field distribution in the moat structure.

The use of a moat termination structure (e.g., including moat 322 and materials lining and/or filling the moat), created either using a single trench 310 or bounded by multiple separate trenches 310, 312, may create an imbalance in the charge seen in the last mesa 314 (sec FIG. 3E) of the active region 308. This charge imbalance can reduce the breakdown capability of the device. One solution to this charge imbalance, according to one or more aspects of the inventive concept, is to selectively vary a width of the last mesa 314 (i.e., the epitaxial layer 304 between a last one of the plurality of active trench structures (313 in FIG. 4C) in the active region 308 and the first (or only) outer trench 310 in the edge termination region 306, proximate the active region 308) to account for the different charge that this mesa experiences.

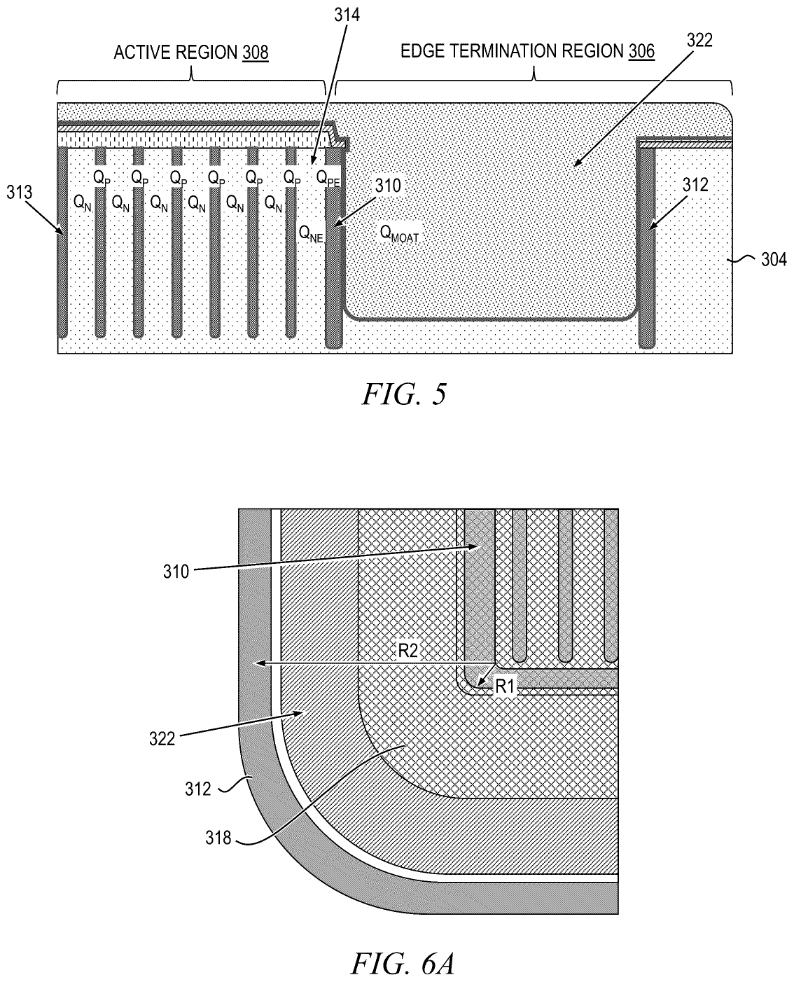

In general, in a charge balanced device, there is a charge balance region where a charge in the charge balance region, Q_{P}, matches a charge in the mesa region, Q_{N}. FIG. 5 is a schematic cross-sectional view depicting at least a portion of the exemplary semiconductor device of FIG. 4A, without the field plate, wherein each of the active trench structures 313 has a fixed charge Q_{P} integrated therein which matches a charge Q_{N} in the mesa regions to thereby implement charge balancing in the device. However, the last mesa 314 bordering the moat structure is no longer bounded by trenches with charge Q_{P}, but rather may have a different charge, Q_{PE}, associated therewith. Although the boundary trench charge Q_{PE} may be the same charge as the charge Q_{P} associated with the other active trench structures 313, this may not necessarily be the case due to differences in processing, dimensions, or other factors. Furthermore, the insulating layer(s) that fill the moat 322 may also have its own fixed charge associated therewith, depending on the type of material filling the moat. As a result of these other factors, the last mesa 314 in the active region 308 may have a charge, Q_{NE}, that is different than the charge Q_{N} associated with the other mesas in the active region.

If the charge Q_{PE} in the boundary trench 310 and the fixed charge in the moat, Qₘₒₐₜ, does not equal the charge Q_{NE} in the last mesa 314, then charge balance may not be achieved and a reduced breakdown voltage will likely result (i.e., Q_{PE}+Qₘₒₐₜ≠Q_{NE}). In this case, the charge in the last mesa Q_{NE} may be modified, according to one or more embodiments, to accommodate this difference in charge. This can be achieved in several ways, including by varying the width (in a horizontal (x) or lateral direction) of the last mesa 314, among other approaches (e.g., modifying the material in the last mesa 314 or moat structure, varying the dimensions of the moat structure, etc.). For example, if Q_{PE}+Qₘₒₐₜ>Q_{NE}, then the width of the last mesa 314 can be increased to thereby increase the charge associated with the last mesa. Likewise, if Q_{PE}+Qₘₒₐₜ<Q_{NE}, then the width of the last mesa 314 can be decreased to reduce the charge associated with the last mesa.

A further consideration is that the moat structure functions essentially as a capacitor that may induce an additional charge on an inside edge of the outer trench 310. This induced charge will be proportional to the applied voltage according to expression Q=CV, where Q is the charge in Coulombs, C is the capacitance in Farads, and V is the potential difference between the plates of the capacitor in volts. The capacitance being proportional to the lateral width (in a horizontal (x) direction) of the moat structure and a relative permittivity of the insulting material(s) (e.g., first and second insulating layers 324, 326) within the moat, the following expression may be obtained:

$${C}_{EDGE} = \frac{{ε}_{0} {ε}_{MOAT}}{w} , \qquad ( 1 )$$

where C_{EDGE} is the capacitance at an edge of the moat structure, ε₀ is a constant representing the permittivity of free space, εₘₒₐₜ is the permittivity of the insulating materials in the moat, and w is the width of the moat 322 (i.e., the distance between an inside edge of the inner boundary trench 310, facing towards the active region 308, and an outside edge of the outer boundary trench 312, facing away from the active region).

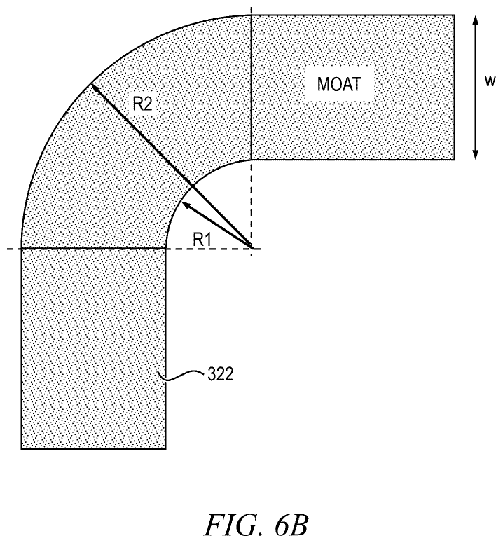

At the device corner, the area of the moat with respect to the active area will be larger and hence the capacitive effect (and impact of fixed charge within the moat) will be greater. The capacitance at the corner of the device, C_{CORNER}, can be determined in accordance with the following expression:

$${C}_{CORNER} = \frac{\frac{π}{2} \cdot {ε}_{0} \cdot {ε}_{MOAT}}{ln ( \frac{R 2}{R 1} )} , \qquad ( 2 )$$

where R1 is an inner radius of the moat, as defined by the outer trench 310, and R2 is an outer radius of the moat, as defined by the boundary trench 312. The inner radius R1 and outer radius R2 are conceptually illustrated in FIG. 6A, which is a schematic plan view depicting at least a portion of a corner in an exemplary semiconductor device employing a moat edge termination structure according to embodiments of the invention. This means that modification of the last mesa 314 in the corner of the device may need to be modified to a larger (or different) extent compared to modification of the last mesa 314 at an edge of the device.

FIG. 6B is a simplified schematic plan view depicting a close-up of a corner of an exemplary semiconductor device employing a moat edge termination structure, according to one or more embodiments of the invention. Referring to FIG. 6B, in order to reduce an impact of the charge in the corner of the device, the capacitance of the moat 322 is preferably reduced; that is, the term ln(R2/R1) in equation (2) above may be increased, which can be achieved by increasing R2 and/or decreasing R1 (i.e., a ratio R2/R1 should be maximized). This essentially means that a larger moat width “w” is required. Since making the width of the moat 322 increases the die area, thereby increasing total die size and cost, it may be more effective to offset the capacitive effect of the moat structure by varying the width of the last mesa 314 instead.

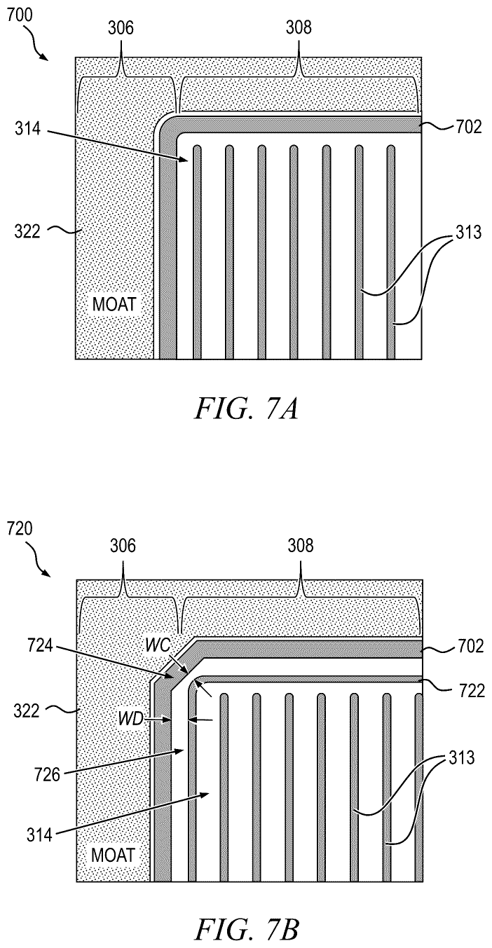

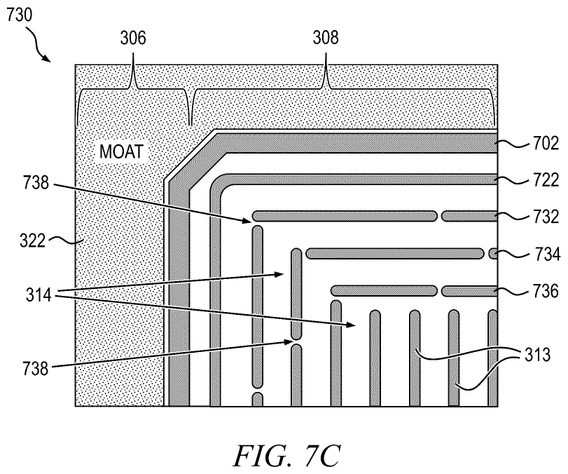

By way of example only and without limitation or loss of generality, FIGS. 7A-7C are plan views conceptually depicting at least a portion of different exemplary configurations of a corner structure in a semiconductor device employing a moat edge termination structure, according to embodiments of the invention. In FIGS. 7A-7C, the at least one outer boundary trench structure (e.g., 312 in FIGS. 4A-4D) is not shown for clarity purposes; it is contemplated, however, that one or more outer boundary trench structures may be optionally employed in the actual device.

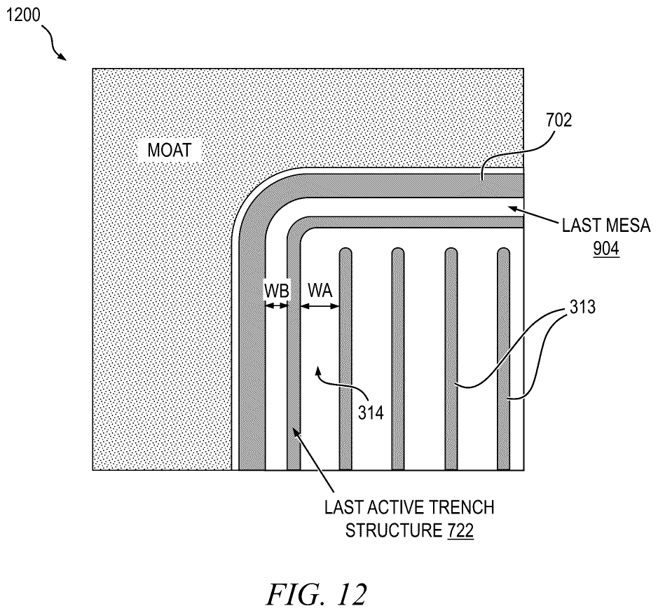

Generally, a series of parallel active trench structures 313 may be formed in the active region 308 of the device, surrounded by (i.e., extending around) an inner boundary trench structure 702, as shown in FIG. 7A. The inner boundary trench structure 702 may be configured having straight sections facing edges of the semiconductor device 700 and a chamfered section 724 at a corner of the device, as in the embodiment of the semiconductor device 720 shown in FIG. 7B. As will be similarly described below in conjunction with FIG. 11, the chamfered inner boundary trench structure 702 allows a horizontal width, WC, of a last mesa 726 (i.e., the epitaxial layer/drift region between a last active trench structure 722 and the inner boundary trench structure 702) at the corner, proximate the chamfered section 724, to be narrower than a horizontal width, WD, along edges of the last mesa 726, when viewed in plan view, at least in part to account for charge imbalances resulting from the moat 322. Alternatively, although not explicitly shown in FIG. 7B, the semiconductor device 720 may be configured such that the last mesa 726 has a substantially constant horizontal width along the sides and corner regions, as will be described further in conjunction with FIG. 12.

In this embodiment, the last active trench structure 722 extends proximate an inner edge of the inner boundary trench structure 702 in both a first direction and a second direction, the first and second directions being parallel to an upper surface of a substrate of the semiconductor device 720 (i.e., in a horizontal plane), the second direction intersecting the first direction. The other active trench structures 313 may be parallel to one another, all extending in either the first direction or the second direction.

FIG. 7C depicts an illustrative semiconductor device 730 according to one or more embodiments of the invention. The semiconductor device 730 may utilize multiple rings of active mesas 314, defined by concentric rings of active trench structures 722, 732, 734 and 736, formed in the active region 308 and adjacent to the inner boundary trench structure 702; each pair of adjacent active trench structures (e.g., 732 and 734) has an active mesa 314 therebetween. Although four concentric rings of active trench structures are shown, embodiments are not limited thereto. An inner-most ring of active trench structures 736 may at least partially surround (i.e., extend around) a second plurality of active area trench structures (inner active area trench structures) 313. Each of the second plurality of active area trench structures 313 may be parallel to one another.

One or more of the concentric rings of active trench structures 722, 732, 734, 736 may optionally be formed with breaks or gaps 738 therein, which may aid in fabrication and/or charge balancing of the device. Specifically, the use of long trenches can add stress to the device causing wafer bow and other manufacturing difficulties, so adding gaps 738 in the trench structures can alleviate this stress. A further benefit of the gaps 738 in the active trench structures 722, 732, 734 and/or 736 is that they can promote current flow between the active trench structures to thereby alleviate current crowding and potentially help reduce hot spots in the device, as heat can also spread more effectively (since the active trench structures may be filled with an insulating material that may be a poor conductor of heat). In the extreme, islands of charge balance regions are better than stripes.

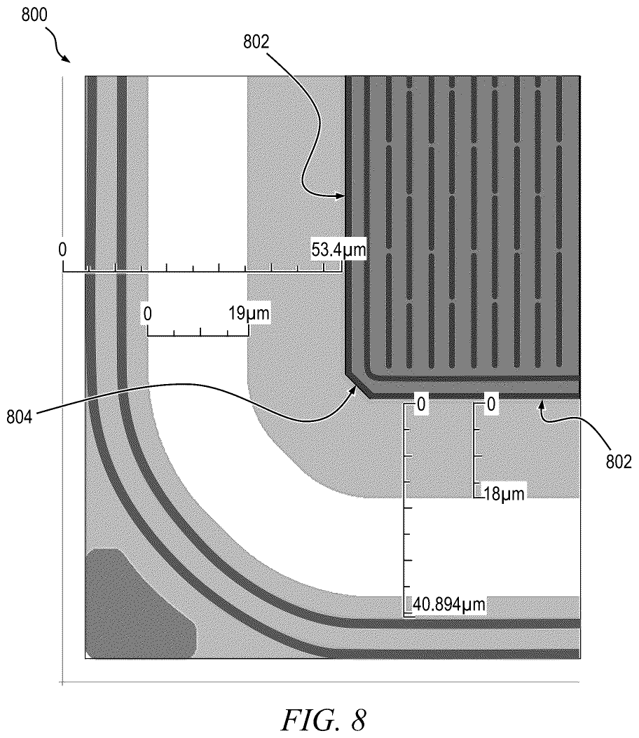

FIG. 8 is a schematic plan view depicting at least a portion of a corner of a semiconductor device 800 employing a moat edge termination structure, according to one or more non-limiting embodiments of the invention. As shown in FIG. 8, the semiconductor device 800 includes an inner boundary trench structure having straight sections 802 along edges of the device 800 and one or more chamfered sections 804 disposed in one or more corresponding corners of the device 800. Measurements are included in FIG. 8 merely to show exemplary dimensions, but it will be appreciated that embodiments of the inventive concept are not limited to any specific dimensions.

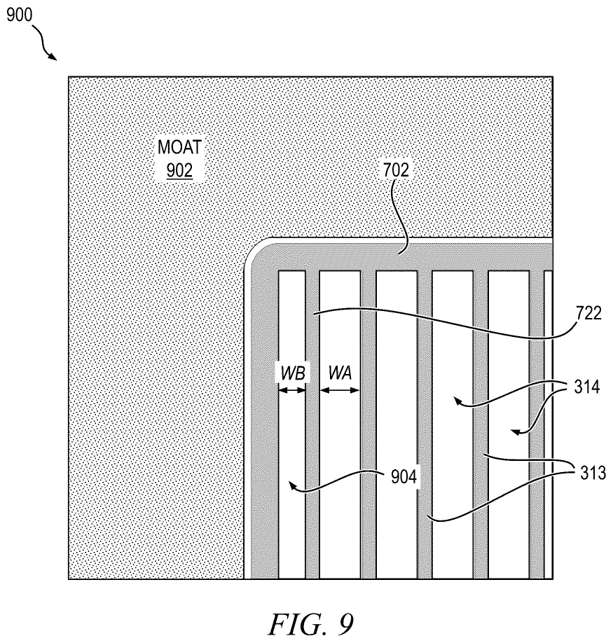

FIGS. 9-16 are schematic plan views depicting at least a portion of several non-limiting examples of illustrative corner structures that may be used in an edge termination region of the semiconductor device employing a moat edge termination structure, in accordance with embodiments of the present invention. It is to be appreciated that these corner structure designs are provided merely to demonstrate different ways of adapting the moat edge termination techniques according to aspects of the inventive concept for implementing enhanced charge balance in the semiconductor device in different applications and systems. Various other designs for corner structures used in an edge termination region of the semiconductor device employing a moat edge termination structure may become apparent to those skilled in the relevant art given the teachings herein.

Referring to FIG. 9, a semiconductor device 900 employing a moat edge termination structure 902 according to one or more embodiments is shown. Note, that an outer boundary of the moat edge termination structure 902 is not shown in FIG. 9 for clarity purposes. In this embodiment, a horizontal width, WB, of a last active mesa 904 (i.e., material between the inner boundary trench structure 702 and the last active trench structure 722) may be less than a horizontal width, WA, of the mesas 314 between other active area trench structures 313 to account for the impact of charge in the moat edge termination structure 902 and/or fixed charge associated with the inner boundary trench structure 702.

In this example embodiment, the active area trench structures 313 are parallel to one another in a first horizontal direction and are spaced apart from one another in a second horizontal direction perpendicular to the first horizontal direction. The active area trench structures 313 extend continuously in the first horizontal direction into the inner boundary trench structure 702, without a gap, although embodiments are not limited thereto. This layout may be most suitable for when there is no charge Q_{PE} in the wider edge termination.

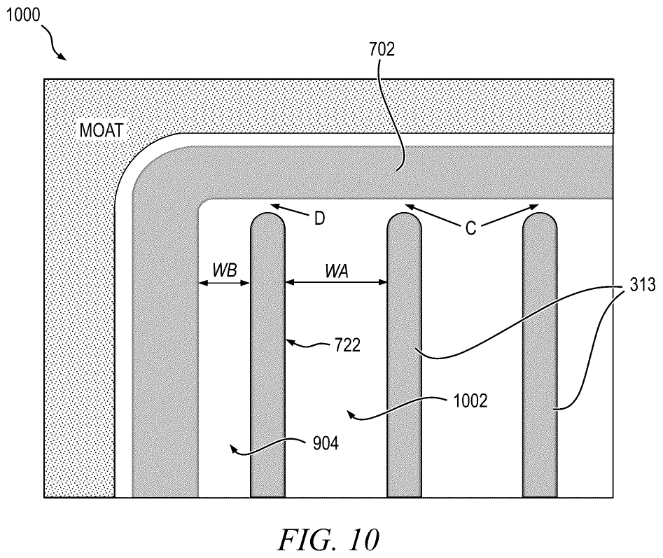

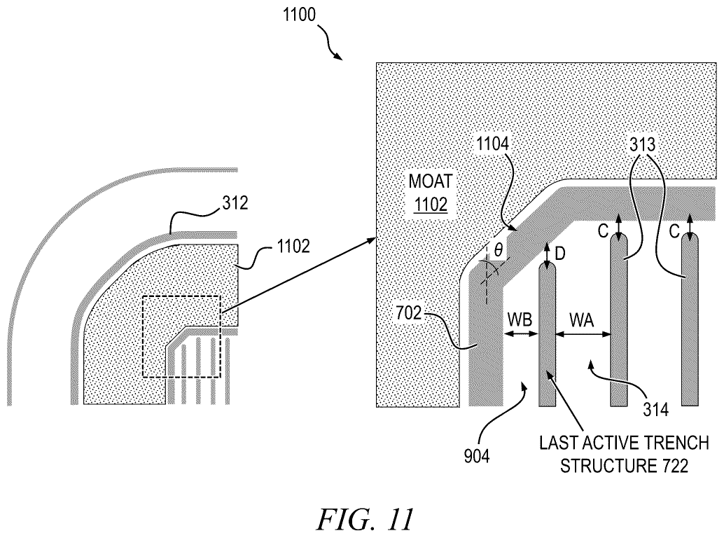

With reference to FIG. 10, given that the moat structure itself in a semiconductor device 1000 according to some embodiments may have some capacitive charge and may have some fixed charge Q_{PE} associated therewith, it may be desirable to incorporate a gap between an end of each of at least a subset of the active area trench structures 313/last active trench structure 722 and the inner boundary trench structure 702 (e.g., gaps “C” and “D”) and/or to modify the width WB of the last mesa 904 relative to the width WA of the active mesa 1002 adjacent to the last mesa 904.

Note, that due to the corner of the semiconductor device 1000 potentially having different compensating charge, the horizontal width of the gap “D” between the end of the last active area trench structure 722 (i.e., the active trench structure closest to the corner) and the inner boundary trench structure 702 may be different than the horizontal width of the gap “C” between other active area trench structures 313 and the inner boundary trench structure 702.

In FIG. 11, a semiconductor device 1100 according to some embodiments may be configured having an edge curvature (which may be defined as a radius of curvature of the outer boundary trench structure 312 in the corner of the semiconductor device 1100 which defines an outer edge of a moat structure 1102) that may be increased by using a small, chamfered section 1104 joining adjacent sides of the inner boundary trench structure 702. In some embodiments, the chamfered section 1104 may be configured having about a 45-degree angle (i.e., angle θ=45 degrees) relative to the adjacent sides of the inner boundary trench structure 702, although embodiments of the invention are not limited to this specific angle or shape. For example, the chamfered section 1104 may be configured having an angle θ less than 45 degrees (e.g., about 40 degrees, or 30 degrees, or less), or the chamfered section 1104 may be configured having an angle θ greater than 45 degrees (e.g., about 50 degrees, or 60 degrees, or greater). This embodiment is similar to the illustrative embodiment of the corner structure 800 in the example semiconductor device 800 shown in FIG. 8.

A width of the gaps “C” and “D” between ends of the active area trench structures 313, 722 and the inner boundary trench structure 702, when viewed in a plan view (i.e., in a horizontal plane), may be adjusted for optimizing charge balance in the semiconductor device 1100, according to one or more embodiments. Alternatively or additionally, the horizontal width WB of the last mesa 904 may be adjusted, relative to the horizontal width WA of the mesas 314 between the other active area trench structures 313, for optimizing charge balance in the semiconductor device 1100.

In FIG. 12, at least a portion of an illustrative semiconductor device 1200 is shown, according to one or more embodiments. The semiconductor device 1200 includes an arrangement of a corner structure wherein the horizontal width WB of the last mesa 904 (i.e., the material between the last active trench structure 722 and the inner boundary trench structure 702) is substantially constant. Note, that this configuration makes all four sides the same, at least from a charge balance perspective.

The active trench structures 313, 722, like the active trench structures 313, 722 shown in FIG. 7B, may be configured such that the last active trench structure 722 extends along an inner edge of the inner boundary trench structure 702 in both the first and second horizontal directions, while the remaining active trench structures 313 may be parallel to one another and extend in one of the first horizontal direction or the second horizontal direction, when viewed in plan view.

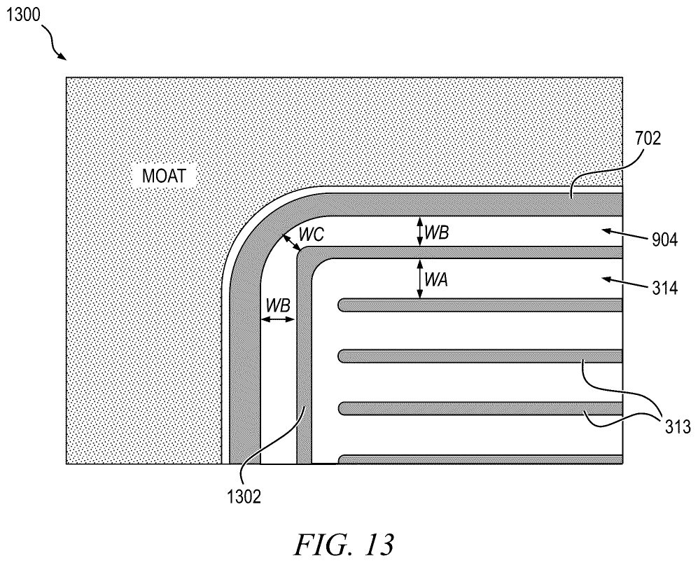

With reference to FIG. 13, at least a portion of an illustrative semiconductor device 1300 is shown, according to one or more embodiments. The semiconductor device 1300 includes an arrangement of a corner structure wherein a horizontal width WB of the last mesa 904, between a last active trench structure 1302 and the inner boundary trench structure 702, is substantially constant along straight edge sections of the last mesa. A width WC of the last mesa 904 may be narrowed at the corner, relative to the width WB of the last mesa 904 in the straight edge sections to account for the different charge balance that may be needed in the corners of the semiconductor device 1300. Furthermore, the widths WB and WC of the last mesa 904 may be different relative to the width WA of the other mesas 314 in the active region, between other adjacent active trench structures 313.

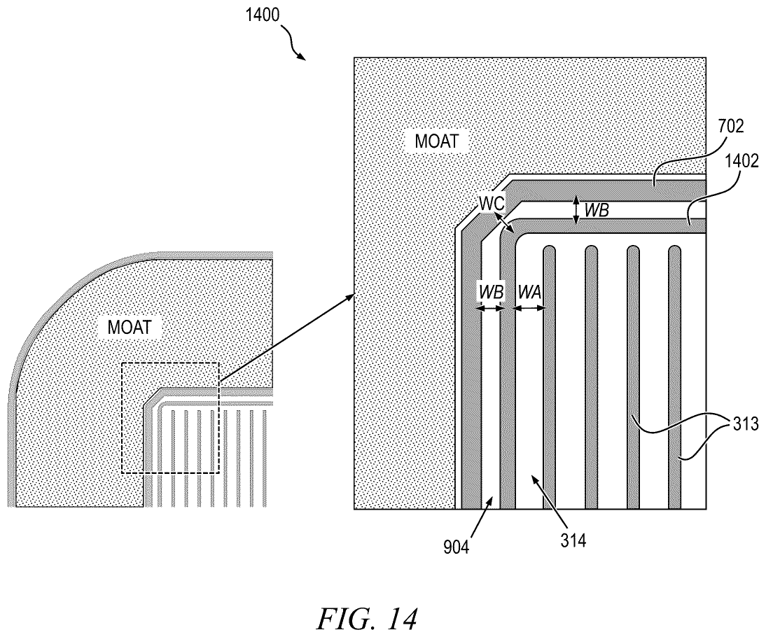

In the embodiment shown in FIG. 14, a semiconductor device 1400 according to one or more embodiments includes a corner structure configured such that the last mesa 904, adjacent to the inner boundary trench structure 702 in the edge termination region, has a constant width WB along straight edges of the die and a narrowed width WC at a corner of the die joining adjacent straight edges (i.e., WC<WB). The width WC of the last mesa 904 at the corner may be narrowed, in this embodiment, by using an inner boundary trench structure 702 configured having a chamfer at the corner rather than a rounded corner. In some embodiments, the chamfer may have an angle of about 45 degrees, although embodiments are not limited thereto. The width WC of the last mesa 904 at the corner of the semiconductor device 1400 and the width WB of the last mesa 904 along the straight edges of the device 1400 may be different than the width WA of the mesas 314 between other active trench structures 313 in the active region of the semiconductor device 1400.

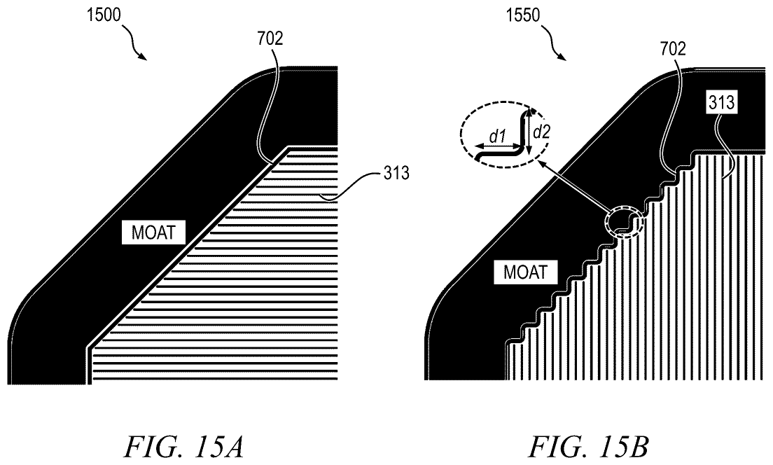

FIGS. 15A and 15B are top plan views depicting exemplary semiconductor devices 1500 and 1550, respectively, according to embodiments of the present invention. Each of the semiconductor devices 1500, 1550 includes a corner structure configured having a chamfer of about 45 degrees at the corner, although embodiments are not limited to any specific shape or angle of the chamfered portion of the corner structure. Each of the semiconductor devices 1500, 1550 further includes a plurality of active trench structures 313 that extend parallel to one another and into or proximate the inner boundary trench structure 702; that is, there may or may not be a gap between ends of the active trench structures 313 and the inner boundary trench structure 702. Note, that the gap in the chamfered section of the inner boundary trench structure 702 may be different compared to the straight sections of the inner boundary trench structure 702.

The active trench structures 313 in the semiconductor device 1500 of FIG. 15A may extend in a first horizontal direction parallel to an upper surface of a substrate of the semiconductor device 1500. The active trench structures 313 in the semiconductor device 1550 of FIG. 15B may extend in a second horizontal direction parallel to the upper surface of a substrate of the semiconductor device 1550, the second horizontal direction intersecting the first horizontal direction (e.g., perpendicular).

The inner boundary trench structure 702 may be a straight-line structure having a prescribed slope (e.g., about 45-degrees), as depicted in the semiconductor device 1500 of FIG. 15A. Alternatively, the inner boundary trench structure 702 may be configured with a stepped (i.e., zig-zag) edge at the corner, having an overall prescribed slope (e.g., about 45-degrees) with respect to adjacent sides of the inner boundary trench structure 702. Embodiments of the invention are not limited to the specific shape or angle at the corner of the inner boundary trench structure 702, although 45 degrees may be preferred in some embodiments.

Referring to FIGS. 15A and 15B, the chamfered corner configuration of the inner boundary trench structure 702 may be implemented, for example, having smooth edges that are angled (e.g., about 45 degrees) at the corner with respect to the adjacent sides of the inner boundary trench structure 702 that are joined at the corner, as shown in FIG. 15A. Alternatively, the chamfered corner configuration of the inner boundary trench structure 702 may be implemented, for example, having stepped (i.e., zig-zag) edges approximating an angled edge at the corner with respect to the adjacent sides of the inner boundary trench structure 702, as shown in FIG. 15B. The steps forming the corner of the inner boundary trench structure 702 in FIG. 15B may be equal in size; that is, a tread dimension d1 may be equal to a riser dimension d2 for each of the plurality of steps forming the corner of the inner boundary trench structure 702, although embodiments are not limited thereto.

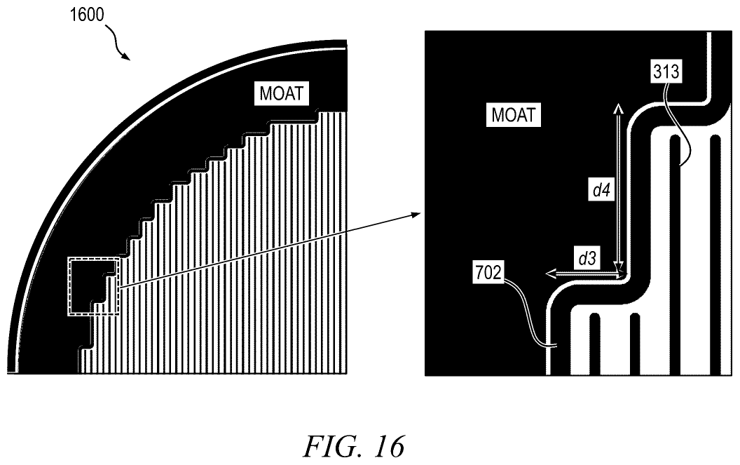

FIG. 16 depicts an illustrative semiconductor device 1600, according to one or more embodiments of the present invention. The semiconductor device 1600 may include an inner boundary trench structure 702 and a plurality of active trench structures 313 extending in parallel with one another into or proximate the inner boundary trench structure 702; that is, there may or may not be a gap between ends of the active trench structures 313 and the inner boundary trench structure 702.

Referring to FIG. 16, rather than being configured having a chamfered corner as shown in FIGS. 15A and 15B, the moat structure in the semiconductor device 1600 of FIG. 16 may be rounded at the corner (e.g., a corner having a large radius of curvature). Like the embodiment shown in FIG. 15B, the rounded corner of the inner boundary trench structure 702 may be configured having stepped edges approximating a prescribed radius of curvature that substantially matches a contour of an inner edge of the moat structure at the corner. The steps forming the corner of the inner boundary trench structure 702 in FIG. 16 may not be equal in size; that is, a tread dimension d3 and a riser dimension d4 of one step may be different than the tread and riser dimensions d3, d4 of another step forming the corner of the inner boundary trench structure 702. Furthermore, for any given step forming the corner of the inner boundary trench structure 702, the tread dimension d3 may not be equal to the riser dimension d4, although d3 and d4 may be equal to one another at certain portions along the curved corner.

Although the present disclosure provides several non-limiting examples of illustrative edge termination structures for use in a charge balanced semiconductor device, various modifications and changes can be made thereto without departing from the scope of the disclosure as set forth in the claims below, as may become apparent to those skilled in the art given the teachings herein. Accordingly, the specification and figures are to be regarded in an illustrative rather than a restrictive sense, and all such modifications are intended to be included within the scope of the present disclosure. Any benefits, advantages, or solutions to problems that are described herein with regard to a specific example are not intended to be construed as a critical, required, or essential feature or element of any or all the claims.

Although the overall fabrication methods and the structures formed thereby are entirely novel, certain individual processing steps required to implement the method may utilize conventional semiconductor fabrication techniques and conventional semiconductor fabrication tooling. These techniques and tooling will already be familiar to those having ordinary skill in the relevant arts given the teachings herein. Moreover, many of the processing steps and tooling used to fabricate semiconductor devices are also described in a number of readily available publications, including, for example: P. H. Holloway et al., Handbook of Compound Semiconductors: Growth, Processing, Characterization, and Devices, Cambridge University Press, 2008; and R. K. Willardson et al., Processing and Properties of Compound Semiconductors, Academic Press, 2001, which are both hereby incorporated herein by reference in their entireties for all purposes. It is emphasized that while some individual processing steps are set forth herein, those steps are merely illustrative, and one skilled in the art may be familiar with several equally suitable alternatives that would also fall within the scope of the invention.

It is to be appreciated that the various layers and/or regions shown in the accompanying figures may not be drawn to scale. Furthermore, one or more semiconductor layers of a type commonly used in such semiconductor devices may not be explicitly shown in a given figure to facilitate a clearer description. This does not imply that the semiconductor layer(s) not explicitly shown are omitted in the actual device.

In one or more embodiments, formation of the exemplary device structures described herein may involve deposition of certain materials and layers by physical vapor deposition (PVD), chemical vapor deposition (CVD), atomic layer deposition (ALD), molecular beam epitaxy (MBE), or any of the various modifications thereof, including, for example, plasma-enhanced chemical vapor deposition (PECVD), metal-organic chemical vapor deposition (MOCVD), low pressure chemical vapor deposition (LPCVD), electron-beam physical vapor deposition (EB-PVD), and plasma-enhanced atomic layer deposition (PE-ALD). The depositions can be epitaxial processes, and the deposited material can be crystalline. In one or more embodiments, formation of a layer can be achieved using a single deposition process or multiple deposition processes, where, for example, a conformal layer is formed by a first process (e.g., ALD, PE-ALD, etc.) and a fill is formed by a second process (e.g., CVD, electrodeposition, PVD, etc.); the multiple deposition processes can be the same or different.

As used herein, the term “semiconductor” may refer broadly to an intrinsic semiconductor material that has been doped, that is, into which a doping agent has been introduced, giving it different electrical properties than the intrinsic semiconductor material, or it may refer to intrinsic semiconductor material that has not been doped. Doping may involve adding dopant atoms to an intrinsic semiconductor material, which thereby changes electron and hole carrier concentrations of the intrinsic semiconductor material at thermal equilibrium. Dominant carrier concentration in an extrinsic semiconductor material determines the conductivity type of the semiconductor material.

The term “metal,” as used herein, is intended to refer to any electrically conductive material, regardless of whether the material is technically defined as a metal from a chemistry perspective or not. Thus “metals” as used herein will include such materials as, for example, aluminum, copper, silver, gold, etc., and will include such materials as, for example, graphene, germanium, gallium arsenide, highly-doped polysilicon (commonly used in most MOSFET devices), etc. This is to be distinguished from the definition of a “metal” from a physics perspective, which usually refers to those elements having a partially filled conduction band and having lower resistance toward lower temperature.

As used herein, the term “insulating” may generally denote a material having a room temperature conductivity of less than about 10⁻¹⁰ (Ω-m)⁻¹. Suitable insulating materials may include, but are not limited to, silicon oxide, silicon nitride, silicon oxynitride, boron nitride, high-dielectric constant (high-k) materials, or any combination of these materials. Non-limiting examples of high-k materials may include, for example, metal oxides, such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate, ceramics, etc. High-k materials may further include dopants such as lanthanum, aluminum, etc.

As used herein, “p-type” may refer broadly to the addition of impurities to an intrinsic semiconductor material that creates deficiencies of valence electrons. In a silicon-containing material, non-limiting examples of p-type dopants (i.e., impurities) include boron, aluminum, gallium and indium.

As used herein, “n-type” may refer broadly to the addition of impurities that contribute free electrons to an intrinsic semiconductor material. In a silicon-containing material, non-limiting examples of n-type dopants include antimony, arsenic and phosphorous.

It will also be understood that when an element such as a layer, region or substrate is referred to as being “atop,” “above,” “on” or “over” another element, it is broadly intended that the element be in direct contact with the other element or intervening elements can also be present. In contrast, when an element is referred to as being “directly on” or “directly over” another element, it is intended that there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present. Furthermore, positional (i.e., directional) terms such as “above,” “below,” “upper,” “lower,” “under,” and “over” as may be used herein, are intended to indicate relative positioning of elements or structures to each other as opposed to absolute position.

At least a portion of the techniques of the present invention may be implemented in an integrated circuit. In forming integrated circuits, identical die are typically fabricated in a repeated pattern on a surface of a semiconductor wafer. Each die includes a device described herein, and may include other structures and/or circuits. The individual die are cut or diced from the wafer, then packaged as an integrated circuit. One skilled in the art would know how to dice wafers and package die to produce integrated circuits. Any of the exemplary structures illustrated in the accompanying figures, or portions thereof, may be part of an integrated circuit. Integrated circuits so manufactured are considered part of this invention.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from having enhanced edge termination structures therein (e.g., power IC devices) formed in accordance with one or more embodiments of the invention.

An integrated circuit in accordance with aspects of the present disclosure can be employed in essentially any application and/or electronic system involving enhanced breakdown voltage structures, such as, but not limited to, power metal-oxide semiconductor field-effect transistors (MOSFETs), Schottky diodes, etc. Suitable systems and applications for implementing embodiments of the invention may include, but are not limited to, AC-DC and DC-DC conversion, motor control, and power supply OR-ing (“OR-ing” is a particular type of application that parallels multiple power supplies to one common power bus in a redundant power system architecture). Systems incorporating such integrated circuits are considered part of this invention. Given the teachings of the present disclosure provided herein, one of ordinary skill in the art will be able to contemplate other implementations and applications of embodiments of the invention.

The illustrations of embodiments of the invention described herein are intended to provide a general understanding of the various embodiments, and they are not intended to serve as a complete description of all the elements and features of apparatus and systems that might make use of the structures and semiconductor fabrication methodologies described herein. Many other embodiments will become apparent to those skilled in the art given the teachings herein; other embodiments are utilized and derived therefrom, such that structural and logical substitutions and changes can be made without departing from the scope of this disclosure. The drawings are also merely representational and are not necessarily drawn to scale. Accordingly, the specification and drawings are to be regarded in an illustrative rather than a restrictive sense.

Embodiments of the invention are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

The corresponding structures, materials, acts, and equivalents of all means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the various embodiments with various modifications as are suited to the particular use contemplated.

The abstract is provided to comply with 37 C.F.R. § 1.72 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, inventive subject matter lies in less than all features of a single embodiment. Thus, the following claims are hereby incorporated into the Detailed Description, with each claim standing on its own as separately claimed subject matter.

Given the teachings of embodiments of the invention provided herein, one of ordinary skill in the art will be able to contemplate other implementations and applications of the techniques of embodiments of the invention. Although illustrative embodiments of the invention have been described herein with reference to the accompanying drawings, it is to be understood that embodiments of the invention are not limited to those precise embodiments, and that various other changes and modifications are made therein by one skilled in the art without departing from the scope of the appended claims.

What is claimed is:

1. A method of forming an edge termination structure in a semiconductor device, the semiconductor device including an active region, in which one or more active structures are formed, and an edge termination region, in which the edge termination structure is formed, the edge termination region being laterally adjacent to the active region, the method comprising:
forming an epitaxial layer on a semiconductor substrate, the epitaxial layer extending laterally across the active and edge termination regions;
forming a plurality of active trenches in the active region and at least one outer trench in the edge termination region, each of the outer and active trenches extending vertically through at least a portion of the epitaxial layer;
at least partially filling each of the outer and active trenches with a first insulating material;
forming a moat by etching an area of the epitaxial layer in the edge termination region proximate to a last one of the plurality of active trenches in the active region;
at least partially filling the moat with a second insulating material to form a moat structure as the non-conducting edge termination structure in a semiconductor device.

2. The method according to claim 1, further comprising:
forming at least one boundary trench in the edge termination region, the boundary trench extending vertically through at least a portion of the epitaxial layer and being spaced laterally from the at least one outer trench; and
at least partially filling the at least one boundary trench with the first insulating material,
wherein the moat structure is disposed between the outer and boundary trenches, such that a given sidewall of the moat structure is defined by one of the outer and boundary trenches.

3. The method according to claim 2, wherein the outer, boundary and active trenches are formed concurrently using a same mask and in a same processing step.

4. The method according to claim 1, wherein a first width of the at least one outer trench is greater than a second width of each of the plurality of active trenches.

5. The method according to claim 4, wherein the first width is at least twice the second width.

6. The method according to claim 2, wherein each of the at least one outer trench, the at least one boundary trench, and the plurality of active trenches is formed using a deep trench etch process having an aspect ratio of greater than about 10 to 1.

7. The method according to claim 1, further comprising forming a first metal layer on an upper surface of at least the active region, wherein the first metal layer is configured to extend laterally over the at least one outer trench and over a portion of the moat structure in the edge termination region, an extension of the first metal layer over the moat structure forming a field plate in the edge termination region.

8. The method according to claim 7, further comprising controlling an amount of extension of the first metal layer over the moat structure in the edge termination region to optimize an electric field distribution in the moat structure.

9. The method according to claim 1, further comprising:
forming a first metal layer on an upper surface of at least the active region; and
forming a second metal layer on an upper surface of the first metal layer and extending laterally over the at least one outer trench and over a portion of the second insulating layer in the moat structure to form a field plate in the edge termination region.

10. The method according to claim 9, further comprising controlling an amount of extension of the second metal layer over the moat structure in the edge termination region to optimize an electric field distribution in the moat structure.

11. The method according to claim 1, further comprising:
forming a first metal layer on an upper surface of at least the active region and extending laterally over the at least one outer trench and a portion of the moat structure in the edge termination region, an extension of the first metal layer over the moat structure forming a first field plate in the edge termination region;
forming a second metal layer on an upper surface of the first metal layer and extending laterally over a portion of the second insulating layer in the moat structure to form a second field plate in the edge termination region; and
controlling an amount of extension of at least one of the first and second metal layers over the moat structure in the edge termination region to optimize an electric field distribution in the moat structure.

12. The method according to claim 2, further comprising:
forming a first metal layer on an upper surface of at least the active region, a first part of the first metal layer extending laterally from the active region, over the at least one outer trench and over a portion of the moat structure, to form a primary inner field plate in the edge termination region; and
forming a second part of the first metal layer extending laterally over the epitaxial layer, over the at least one boundary trench and over a portion of the moat structure, to form a primary outer field plate in the edge termination region.

13. The method according to claim 2, further comprising:
forming a first metal layer on an upper surface of at least the active region, a portion of the first metal layer extending laterally over the epitaxial layer, over the at least one boundary trench and over a portion of the moat structure proximate the at least one outer trench, to form a primary outer field plate in the edge termination region; and
forming a second metal layer on an upper surface of the first metal layer and extending laterally over a portion of the second insulating layer in the moat structure proximate the at least one outer trench, to form a secondary outer field plate in the edge termination region.

14. The method according to claim 2, further comprising:
forming a first metal layer on an upper surface of at least the active region;
forming a first part of a second metal layer on an upper surface of the first metal layer and extending laterally over the at least one outer trench and a portion of the second insulating layer in the moat structure proximate the at least one outer trench to form an inner field plate in the edge termination region; and
forming a second part of the second metal layer on the second insulating layer over the at least one boundary trench and a portion of the moat structure proximate the at least one boundary trench to form an outer field plate in the edge termination region.

15. The method according to claim 14, further comprising controlling an amount of extension of the first and second parts of the second metal layer over the moat structure in the edge termination region to optimize an electric field distribution in the moat structure.

16. The method according to claim 1, further comprising forming the at least one outer trench and the moat such that a depth of the at least one outer trench is greater than a depth of the moat in the edge termination region.

17. The method according to claim 1, further comprising controlling a width of a mesa area between a last one of the plurality of active trenches in the active region and the outer trench in the edge termination region to accommodate a difference in charge between the moat structure and the plurality of active trenches.

18. A semiconductor device including an active region and an edge termination region, the edge termination region being laterally adjacent to the active region, the semiconductor device comprising:
an epitaxial layer formed on a semiconductor substrate, the epitaxial layer extending laterally across the active and edge termination regions;
a plurality of active trench structures and at least one active device formed in the active region, each of the active trench structures extending vertically through at least a portion of the epitaxial layer and being at least partially filled with a first insulating material;
at least one outer trench structure formed in the edge termination region, the outer trench structure extending vertically through at least a portion of the epitaxial layer and being at least partially filled with the first insulating material, the outer trench structure being proximate to a last one of the plurality of active trench structures in the active region; and
a moat structure extending vertically through at least a portion of the epitaxial layer in the edge termination region, the moat structure having a sidewall defined by the at least one outer trench structure, the moat structure being at least partially filled with a second insulating material, the moat structure forming an edge termination structure in the semiconductor device configured to laterally isolate the active region from a reverse voltage in the semiconductor device.

19. The semiconductor device according to claim 18, further comprising:
at least one boundary trench structure formed in the edge termination region, the boundary trench structure extending vertically through at least a portion of the epitaxial layer and being at least partially filled with the first insulating material, the boundary trench structure being spaced laterally from the at least one outer trench structure,
wherein the moat structure is disposed between the outer and boundary trench structures, such that a given sidewall of the moat structure is defined by one of the outer and boundary trench structures.

20. The semiconductor device according to claim 18, further comprising:
a first metal layer on at least an upper surface of the plurality of active trench structures in the active region; and
a second metal layer on the second insulating layer over at least a portion of the moat structure, the second metal layer forming a field plate for controlling an electrical field distribution in the moat structure.

21. The semiconductor device according to claim 18, further comprising:
a first metal layer on at least an upper surface of the plurality of active trench structures in the active region, wherein the first metal layer extends laterally over the outer trench structure and over at least a portion of the moat structure, an extension of the first metal layer over the moat structure forming a first field plate in the edge termination region; and
a second metal layer disposed on the second insulating layer over at least a portion of the moat structure, the second metal layer forming a second field plate in the edge termination region,
wherein an amount of extension of at least one of the first and second metal layers over the moat structure in the edge termination region in configured to control an electric field distribution in the moat structure.

22. The semiconductor device according to claim 18, wherein each of at least a subset of the plurality of active trench structures in the active region is at least partially filled with material having a fixed charge associated therewith, so that the plurality of active trench structures are configured to charge balance at least a portion of the active region.

23. The semiconductor device according to claim 19, wherein the at least one boundary trench structure is at least partially filled with material having a fixed charge associated therewith, so that the at least one boundary trench structure is configured to charge balance at least a portion of the edge termination region.

24. The semiconductor device of 18, wherein a width of a mesa area between a last one of the plurality of active trenches in the active region and the outer trench in the edge termination region is configured to accommodate a difference in charge between the moat structure and the plurality of active trenches.
